(19) United States
(12) Patent Application Publication
(10) Pub. No.: US 2007/0069393 A1
(43) Pub. Date: Mar. 29, 2007

(54) Wiring board embedded with spherical semiconductor element

(76) Inventors: Toshiyuki Asahi, Osaka (JP); Yukihiro Ishimaru, Osaka (JP); Tousaku Nishiyama, Nara (JP); Seiichi Nakatani, Osaka (JP); Yasuhiro Sugaya, Osaka (JP)

Correspondence Address: WENDEROTH, LIND & PONACK L.L.P., 2033 K. STREET, NW, SUITE 800, WASHINGTON, DC, 20006, US

(21) Appl. No.: 10/565,378

(22) PCT Filed: Jul. 22, 2004
(86) PCT No.: PCT/JP04/10756

§ 371 Date: Nov. 14, 2006

(30) Foreign Application Priority Data
Jul. 24, 2003 (JP) 2003-279110
Sep. 12, 2003 (JP) 2003-321325

(51) Int. Cl. H01L 23/48

(52) U.S. Cl. 257/780

(57) ABSTRACT

A double-sided or multilayer wiring board having high-density wiring is obtained by embedding a spherical semiconductor element in an electrically insulating substrate which composes the wiring board, and a thin electronic device can be provided using such a wiring board. Furthermore, a flexible double-sided or multilayer wiring board which is capable of being housed in a limited space while keeping a desired form can be provided by embedding the spherical semiconductor element, and a thin electronic device can be provided using a variety of such wiring boards by imparting different types of flexibility to desired parts of such a wiring board as required.

### CROSS-REFERENCE TO RELATED APPLICATIONS

The present application claims priority under the Paris Convention to Japanese Patent Application No. 2003-279110 (filed on Jul. 24, 2003 entitled “SPHERICAL SEMICONDUCTOR MOUNTING BODY AND ELECTRONIC DEVICE USING THE SAME” and Japanese Patent Application No. 2003-321325 (filed on Sep. 12, 2003 entitled “SPHERICAL SEMICONDUCTOR EMBEDDED WIRING BOARD AND ELECTRONIC DEVICE USING THE SAME.” The contents of those applications are incorporated herein by reference thereto in their entirety, so that they form a part of the present description.

### TECHNICAL FIELD

The present invention relates to a device in which a spherical semiconductor element (i.e. ball semiconductor element) is used, and a production process of such device. For example, the present invention relates to a wiring board including a spherical semiconductor element which is compact and also has a high performance in addition to a high density wiring as well as a passive element, and also relates to a production process of such wiring board. In addition, the present invention relates to a double-sided or multilayer wiring board having an embedded spherical semiconductor element which board is mounted in a thin and compact mobile electronic device such as a mobile phone, a video camera, digital camera or the like, and particular to such wiring board in which electronic connection(s) is formed between inside wiring patterns, between outside wiring patterns, and/or between an inside wiring pattern and an outside wiring pattern so as to form an electronic circuit.

### BACKGROUND ART

Recently, electronic devices for both of industrial and domestic uses such as a laptop PC, a mobile phone, a digital camera and the like have become highly compact, light and thin in addition to becoming sophisticated and multifunctional by mounting a number of highly integrated semiconductor elements (that is, LSIs).

In the field of a wiring board on which surface a semiconductor element, a variety of electronic parts and the like are mounted, a resin multilayer wiring board in which an inner via hole is formed though all of the layers is proposed, and also a three-dimensionally mounted module is proposed for the purpose of higher density part mounting and being slim in which module micro chip parts of a semiconductor bare chip, a resistor, a capacitor and the like are mounted inside a multilayer wiring board (see for example Patent Document 1 shown below). Based on such techniques, more compact and thinner electronic device is now under development by miniaturizing a circuit by about one quarter which has the same function as in the case of the surface amounting wiring of the prior art.

One representative of such electronic device which has rapidly become more compact and thinner is a mobile phone, and its dissemination is remarkable. The mobile phone which was of a single housing type is now mainly of a folding type having two housings because more convenient portability is expected and also a larger display is desirable for the purpose of the adaptation to a number of functions such as a internet information search function, a mailing function, and the like.

FIG. 27 schematically shows one example of a folding type mobile phone of the prior art. FIG. 27(a) shows a cross sectional view of the mobile phone along its longitudinal direction, FIG. 27(b) shows a cross sectional view of the mobile phone along a line A-A in FIG. 27(a), FIG. 27(c) shows a plain view of a printed wiring board which is used for the mobile phone, FIG. 27(d) shows a side view along its longitudinal direction, and FIG. 27(e) shows a side view of the printed wiring board which is in its folded situation when it is to be contained in the mobile phone.

As shown in FIG. 27(a), a liquid crystal display 202 and its driving module 203 as main parts are contained in an upper surface of a display side housing 201. An input side housing 204 contains an input operation part 205 such as a key board in its upper surface and a cell 206.

The printed wiring board 207 which electrically connects the above mentioned parts so as to function as a mobile phone is composed of an upper wiring board 207a contained in the display side housing 201, a lower wiring board 207b contained in the input side housing 204 and a flexible connecting wiring board 207c which connects the upper and lower wiring boards. The flexible connecting wiring board 207c is contained in a hinge part 208 which pivotally connects the display side housing 201 and the input side housing 204. In the shown example, the flexible connecting wiring board 207c is connected to the upper wiring board and the lower wiring board through connectors 209 respectively. It is noted that in the above mentioned mobile phone, an antenna 210 is located in the input side housing 204, and there is another example in which an antenna is located in the display side housing 201.

A semiconductor element which is used in the above mentioned printed is mounted on a wiring board as a bare chip which is provided by forming a number of LSI circuits are formed by sophisticated photolithographic technique on one surface of a silicon single crystal substrate as a wafer, and then scribing separately. Alternatively, a packaged type chip may used in place of such bare chip. Such semiconductor element is a plate type semiconductor element from a viewpoint of its form, and its integrated circuits are formed on only one side of the plate type element because of its production process. Further, such semiconductor elements are mounted on a wiring board two dimensionally (that is, on an extending direction of a plane of the wiring board), so that the number of the IC circuits which are mounted on a unit mountable area of the plate type semiconductor element, which means a low utilization efficiency of the mountable area.

The production of the plate type semiconductor element requires a large initial investment. To the contrary, a spherical semiconductor element (ball semiconductor element) has been recently developed which requires a lower initial investment, allows three-dimensional design and has an improved mechanical strength. For example, an American company of the spherical semiconductor element proposes that a semiconductor circuit is formed on a surface of a sphere having a diameter of about 1 mm, which is used in a micro-electronic device such as a card type electronic device (see for example Patent Documents 2 and 3 shown below).

Such spherical semiconductor element provides a possibility to achieve circuit integration which is about three times as large as that of the plate type semiconductor element. Further, there are a variety of proposals as to interconnection between the spherical semiconductor elements, direct mounting of the spherical semiconductor element onto a wiring board and the like (see for example Patent Documents 4 and 5 shown below). Each of those proposals intends to achieve speed up, miniaturization or the like of an electronic circuit by utilizing the features of being spherical of the semiconductor element.

Now, a structure of a device using the spherical semiconductor element is proposed in which a spherical semiconductor element 1103 having bumps 1102 is mounted on a main surface of a substrate 1101 as shown in FIG. 28, and also another structure in which spherical semiconductor elements 1211(a), 1211(b) and 1211(c) are mounted along the third dimension direction (that is, horizontally) through bumps 1211 in a cluster form on a main surface of a substrate 1213 as shown in FIG. 29.

The Patent Documents which are related to the present invention are as follows:

Patent Document 1: Japanese Patent Kokai Publication No. 1999-220262 (FIG. 1)

Patent Document 2: U.S. Pat. No. 5,955,776

Patent Document 3: U.S. Pat. No. 6,004,396

Patent Document 4: Japanese Patent Kokai Publication No. 2000-216335 (FIG. 1)

Patent Document 5: Japanese Patent Kokai Publication No. 2000-349224 (FIG. 2)

The contents of those applications are incorporated herein by reference thereto in their entirety.

### DISCLOSURE OF THE INVENTION

However, in the embodiments of the above mentioned devices, the spherical semiconductor element(s) is used by merely mounting it onto a surface the substrate. As far as the surface mounting is used, the number of the bumps which connect the spherical semiconductor element to a multilayer wiring board is limited, which leads to a number of constraints as to wiring. On the other hand, when considering that a passive element is formed in a device, a passive element other than an inductor element is formed in or on a substrate, or a passive element is surface-mounted, which causes a considerable constraint upon the formation of a wiring, so that there are a number of problems when the spherical semiconductor element is used for a variety of applications.

Further, when a device wherein the spherical semiconductor element is used is considered, a thickness of the device becomes large even though a standard spherical semiconductor element having a diameter of 1 mm is used. As a result, a region where the spherical semiconductor element is used is limited. This means that it is impossible to construct an design having a function while exploiting the thickness of the spherical semiconductor element. That is, in the prior art, since the spherical semiconductor element is surface-amounted, such design is impossible.

In the case of the plate type semiconductor element, extended electrodes are all formed on only one side of the element. FIG. 30 schematically shows a cross sectional view of a substrate in which the plate type semiconductor is embedded. As shown, in order to electrically connect a wiring pattern 1302a formed on one main surface of the substrate which is connected to the extended electrodes 1305 to a wiring pattern 1302b which is formed on the other main surface of the substrate, a via hole conductor (or inner via structure) 1303 is used. In such embodiment, there is a constraint as to the design in for example that even the smallest pitch between the via hole conductors should be larger than a diameter of a land electrode such as 1302c or 1302d which is located at the end of the via hole conductor, so that miniaturizing of the substrate size, and thus making the higher density has limitations.

Further, since the wiring board is formed with using a thermosetting resin and a fabric such as a non-woven fabric, the wiring board is rigid as a whole and it is impossible to arbitrarily inflected it, which makes it difficult to contain the wiring board in a limited space of an electronic device which should be miniaturized and thin.

For example, it is hard to house the wiring board in a very limited space of a mobile phone while it is inflected, and also there is a limitation in the reduction of the thickness of the wiring board. In FIG. 27(b) which is a cross sectional view along a line A-A in FIG. 27(a) for example, a back surface 201a of the displaying side housing 201 is curved so as to keep holding feeling good when talking with the phone, so that there is formed a space “S” between the back surface 201a and the upper wiring board 207a which make it impossible to reduce the thickness of the displaying side housing 201. In addition, since the upper wiring board 207a and the lower wiring board 207b are rigid, they cannot be inflected. In order to connect those two wiring board while keeping the arbitrary inflection between them possible as shown in FIG. 27(e), the flexible connecting wiring board 207c is required. The connection between the flexible connecting wiring board 207c and the two wiring boards 207a and 207b should be carried out by means of the connectors 209 or soldering, which makes it difficult to have a thin thickness of the wiring board as a whole.

The present inventors have found that a double-sided or multilayer wiring board having high-density wiring is obtained by embedding a spherical part, particularly a spherical semiconductor element in an electrically insulating substrate which composes the wiring board, so that a thin electronic device can be provided using such a wiring board. Further, they have found that by embedding a spherical semiconductor element, a flexible double-sided or multilayer wiring board is provided which is housed in a limited space while keeping its desired form therein, and also that such wiring board may have different flexibilities in different regions as required, so that a thinned electronic device may be produced while using various such wiring boards.

The present invention provides a wiring board (or a mounting body) which comprises at least one spherical semiconductor element, an electrically insulating substrate and a predetermined wiring pattern which is located on each main surface of the substrate, in which wiring board the electrically insulating substrate is made of a resin composition (which contains preferably a curable resin, and particularly thermosetting resin), and the wiring pattern formed on one main surface of the electrically insulating substrate and the wiring pattern formed on the opposite main surface are electrically connected through a wiring formed on a surface of the spherical semiconductor element, and the spherical semiconductor element is embedded at least partially in the electrically insulating substrate, that is a portion or a whole of the spherical semiconductor element is embedded in the electrically insulating substrate. It is noted that the spherical semiconductor element having the wiring on its surface is an element which is well known in the field of the related art, and it is disclosed in for example the above mentioned Patent Documents. Although the spherical semiconductor element requires a supporting means to keep it in a predetermined position due to its form, such requirement is eliminated by embedding it in the electrically insulating substrate. In other words, embedding automatically functions as such means.

The electrically connecting between the wiring patterns located on the both main surfaces by means of the wiring of the spherical semiconductor element may be direct or indirect. That is, the electrical connection between the wiring located on the surface of the spherical semiconductor element and the wiring pattern may be such that the wiring on the surface of the spherical semiconductor element is connected directly to the wiring pattern or such that the wiring on the surface of the spherical semiconductor element is connected to the wiring pattern by way of “other electric conductor” (for example, other wiring pattern, other wiring, a via hole conductor, an electric part such as a resistor or the like). It is noted that the expression of “connected directly” includes formation of the electric connection with using an element which is usually used for forming the electric connection. Such element is for example a conductive adhesive, a bump, a land, a pad or the like, and it is not included by the above mentioned “other electric conductor.” At least one of the predetermined wiring patters located on the both main surfaces of the electrically insulating substrate may be an electrode (or a terminal or port) of a semiconductor element, an electronic part or the like. For example, such semiconductor element or electronic part is directly mounted on one main surface of the wiring board and its electrode functions as the predetermined wiring pattern of the wiring board according to the present invention. As a result, such electrode is electrically connected to the wiring of the spherical semiconductor element.

When a plate type semiconductor element is embedded in a substrate, a manner using a through hole or a inner via structure, that is, a manner using a via hole conductor has been employed for electrically connecting wiring patterns located on a main surface and its opposite surface which patterns are connected to the semiconductor element. In the wiring board according to the present invention, the wiring patters located on one main surface and its opposite surface respectively are electrically connected via the wiring formed on the spherical semiconductor element. That is, in the wiring board according to the present invention, the wiring located on the surface of the spherical semiconductor element can connect the wiring patterns located on the both sides of the electrically insulating substrate in place of the via hole conductor, so that the wiring patterns may be formed with a narrower pitch, which allows a higher density wiring.

It is noted in the wiring board according to the present invention that it is not necessarily required for all of the wiring patters the electrically insulating substrate has to be connected by the wiring(s) formed on the surface of the spherical semiconductor element, and it is sufficient that at least one wiring pattern formed on one main surface of the electrically insulating substrate and at least one wiring pattern formed on the other main surface which is opposite to said “one main surface” are electrically connected directly or indirectly via at least one wiring which is formed on the surface of the spherical semiconductor element. The other wiring pattern(s) may be connected via a conventional connecting means such as a via hole conductor. It is noted that the number of the wirings formed on the surface of the spherical semiconductor element is not particularly limited, and it may be one or plural, and appropriate number is selected depending on the purpose of the wiring board.

In the wiring board according to the present invention, at least one spherical semiconductor element is present. Namely, the number of the spherical semiconductor element may be one or plural. When a plurality of the spherical semiconductor elements are present, they may be separate from each other or at least some of them may be directly or indirectly connected electrically. The meanings of “directly” and “indirectly” are the same as explained in the above. Concretely, a plurality of the spherical semiconductor elements are embedded in the electrically insulating substrate along its thickness direction and/or its spreading direction (i.e. its surface extending direction of the substrate).

There may be at least other wiring pattern inside the wiring board according to the present invention. Thus, such wiring board corresponds to a multilayer wiring board. When such other wiring pattern is absent, the wiring board according to the present invention corresponds to a double-sided wiring board. When necessary, such other wiring pattern may be connected directly or indirectly to at least one selected from the spherical semiconductor element, the wiring pattern(s) located on the main surface(s) of the electrically insulating substrate, and at least one of via hole conductor(s) and electronic part(s) which will be described later. The meanings of “directly” and “indirectly” are the same as explained in the above.

One preferable embodiment of the wiring board according to the present invention, a passive element is also embedded in the electrically insulating substrate. Usually, an inductor can be formed in the spherical semiconductor element by forming a wiring pattern in the form of a coil, however it has been difficult to form a resistor element or a capacitor element in the spherical semiconductor element. In the above embodiment, the passive element can be embedded in the electrically insulating substrate in which the spherical semiconductor element is embedded, so that a single wiring board can work as a completed system function. Therefore, a very small semiconductor device may be provided of which size is in the same order as that of the spherical semiconductor element to be embedded and within which the system function is completed.

In a particularly preferable embodiment, the passive element is connected through a via hole conductor to at least one of the wiring patterns located on the both main surfaces. With the via hole conductor, flexibility as to a locating position of a general chip part such as a passive element is improved, which is desirable for circuit designing. For example, the spherical semiconductor element can be located most closely to a capacitor, and therefore the wiring board may effectively function as a bypass capacitor.

One preferable embodiment of the wiring board according to the present invention, a portion of the spherical semiconductor element is embedded in the electrically insulating substrate and one or plural, preferably many bumps are formed around a periphery of the remaining portion of the spherical semiconductor element which portion is exposed from the electrically insulating substrate. Such bumps are connected to the wiring pattern formed on the main surface of the electrically insulating substrate. In the conventional mounting, since the spherical semiconductor element is located on and mounted onto through bumps formed on the spherical semiconductor element, there are a number of constraints upon the circuit formation as to the mounting position of the spherical semiconductor element, the number of the bumps to be formed and the like. However, the wiring board according to the present invention in which a portion of the spherical semiconductor element is embedded in the electrically insulating substrate allows the wiring pattern to be connected via the bumps which are formed on the spherical semiconductor element or the electrically insulating substrate around the periphery (corresponding to a latitude line of a sphere) which is located on a border between the spherical semiconductor element and the electrically insulating substrate. Since by appropriately selecting an embedding depth of the spherical semiconductor element, a size of the periphery (i.e. a perimeter) can be changed as required, the flexibility upon the circuit formation as to the mounting position of the spherical semiconductor element, the number of the bumps to be formed and the like is greatly improved.

One preferable embodiment of the wiring board according to the present invention, the electrically insulating substrate is transparent. Such wiring board can be used for a photovoltaic device, a light emitting device and the like. When such device is in the spherical form, a material which is transparent along any direction is desirably used for the electrically insulating substrate so as to utilize characteristics of the spherical device. For the application of the wiring board according to the present invention to the light emitting device as described above, an ITO material is preferably used for an electrode as the wiring pattern.

One preferable embodiment of the wiring board according to the present invention, the electrically insulating substrate is made of a mixture as a resin composition which contains an inorganic filler and a thermosetting material. Most part of the spherical semiconductor element is usually made of a silicon material. When such spherical semiconductor element is embedded in the electrically insulating substrate, it is desirable that a thermal expansion coefficient of the electrically insulating substrate is close to that of the spherical semiconductor element. In the case in which the electrically insulating substrate is made of the mixture which contains the inorganic filler and the thermosetting resin, the type of the thermosetting resin, the type of the inorganic filler and a mixing ratio of them and the like may be adjusted so that the thermal expansion coefficient of the electrically insulating substrate is near that of for example the silicon material.

The above mentioned wiring board according to the present invention can be produced by a process of producing a wiring board which contains a spherical semiconductor element comprising the steps of:

(1-a) embedding the spherical semiconductor element totally in a prepreg substrate (preferably in the form of a sheet) which is made of a curable resin composition in its uncured condition;

(1-b) forming respectively, on carrier sheets, bumps and wiring patterns which are to be connected through a wiring of the spherical semiconductor element so as to obtain an upper wiring pattern transfer material and a lower wiring pattern transfer material;

(1-c) locating and aligning each of the above mentioned wiring pattern transfer sheets, through a resin sheet in its uncured condition, on each side of the prepreg substrate in which the spherical semiconductor element is embedded, followed by heating with pressing so as to integrally bond them, whereby the prepreg substrate and the uncured resin sheets are made into an electrically insulating substrate while the wiring patterns are connected with the wiring of the spherical semiconductor element; and

(1-d) removing the carrier sheets and leaving the wiring patterns and the bumps on the electrically insulating substrate so as to transfer them.

According to the above process, a wiring board as shown in FIG. 1 is obtained as described later. Throughout the present description, the numeral in the parentheses, for example “1” of (1-a) is intended to mean that the step relates to the process which is explained first so as to expediently distinguish a step of a process which will be explained later.

It is noted that in the processes of producing the wiring board according to the present invention which are explained above and also below, the wiring located on the surface of the spherical semiconductor element may include a terminal electrode which is to be connected to the wiring pattern. The bump of the transfer material is for connecting the wiring pattern and the wiring of the spherical semiconductor element, and it is formed correspondingly to a location of the connection.

In one embodiment of the above mentioned production process, the spherical semiconductor element may be embedded not totally but mostly in the step (1-a) so that portions of the spherical semiconductor element are exposed above one and the other main surfaces of the prepreg substrate, and exposed portions of the wiring on the surface of the spherical semiconductor element may have terminal electrodes which are connected to the wiring patterns.

It is noted that the resin sheet used in the step (1-c) is placed between the transfer material and the prepreg substrate with the embedded spherical semiconductor element, and allows ready connection between the wiring pattern and the wiring (preferably its terminal electrode) of the spherical semiconductor element through the bumps similarly to the conventional flip chip amounting in which a non-conductive film (NCF) is used. Upon heating with pressing of the prepreg sheet while the embedded spherical semiconductor element, the resin sheets and the transfer materials stacked together, the resin sheets function as cushions which buffer the applied pressure.

The resin of the resin sheet is in the uncured condition, and such sheet is usually made of a curable resin, particularly a thermosetting resin. Thus, the resin has not been cured (i.e. in the uncured condition) before heating in the step (1-c), and it may optionally be in a semi-cured condition. The material which forms the resin sheet may be the same as a material which is used for the electrically insulating substrate.

In the processes of producing the wiring board according to the present invention which are described above and below, such resin sheet may be omitted when necessary. For example, when a thickness of the prepreg substrate is larger than a diameter of the spherical semiconductor element, and therefore a distance from the main surface of the prepreg substrate to the spherical semiconductor element is larger, the resin sheet may be omitted since a surface layer of the prepreg substrate has a function as a cushon as described above. To the contrary, when the distance from the main surface of the prepreg substrate to the spherical semiconductor element is small or substantially zero, the resin sheet is required. Further with the above mentioned production process, the spherical semiconductor element may be embedded not totally but embedded such that a portion of the spherical semiconductor element is exposed in the step (1-a), and in such case, the production process is carried out while the resin sheets are sandwiched of the spherical semiconductor element as in the step (1-c).

It is noted that those skilled in the art readily understand in the wiring board and its production process which are explained above and below that the electric members which form the wiring board (for example, the spherical semiconductor element and its wiring, the wiring pattern, the electronic part, the passive element, the via hole conductor, the conductive thin layer, the conductive adhesive, the conductive paste and the like) are connected as predetermined so as to form a desired circuit. Also, it is noted that based, on the disclosure of the present description, those skilled in the art are able to produce the wiring board and the electronic device comprising the same according to the present invention and also to carry out the production process of the wiring board according to the present invention.

The above explanations as to the resin sheet are also applicable as well to the resin sheet used in the production process of the wiring board which will be described later.

With the production process according to the present invention, since the bump which connects the wiring pattern on the transfer material and the wiring of the spherical semiconductor element is formed on the transfer material, the production of the wiring board becomes easier and also the flexibility upon designing the wiring board is greatly improved. It is noted that in the above mentioned production process, the wiring patterns are transferred, surfaces of the wiring patterns are flushed with the surfaces of the electrically insulating substrate. When the wiring pattern is not located on or near a pole of the spherical semiconductor element (i.e. a point corresponding to a north pole or a south pole of a sphere), the pole of the spherical semiconductor element can be located can reach the surface of the electrically insulating substrate.

The above mentioned wiring board according to the present invention can be produced by a process of producing a wiring board which contains a spherical semiconductor element comprising the steps of:

(2-a) embedding a portion of the spherical semiconductor element (preferably at least half of the spherical semiconductor element based on its volume) in a prepreg substrate (preferably in the form of a sheet) which is made of a curable resin composition in its uncured condition, so that a portion of the spherical semiconductor element is exposed above at least one main surface of the prepreg substrate

(2-b) forming respectively, on carrier sheets, bumps and wiring patterns which are to be connected through a wiring of the spherical semiconductor element so as to obtain an upper wiring pattern transfer material and a lower wiring pattern transfer material, provided that as to the transfer material which is, in the following step (2-c), placed on a side of the prepreg substrate on which side the portion of the spherical semiconductor element is exposed, a hole is also formed through the carrier sheet which hole such portion is able to pass through;

(2-c) locating and aligning each of the above mentioned wiring pattern transfer sheets, through a resin sheet in its uncured condition (provided that a hole is formed through the resin sheet which is to be placed on the side of the prepreg substrate on which side the portion of the spherical semiconductor element is exposed), on each side of the prepreg substrate in which the spherical semiconductor element is embedded while the exposed portion of the spherical semiconductor element is located through the holes of the carrier sheet and the resin sheet, followed by heating with pressing them so as to integrally bond them, whereby the prepreg substrate and the uncured resin sheets are made into an electrically insulating substrate while the wiring patterns are connected to each other with the wiring of the spherical semiconductor element; and

(2-d) removing the carrier sheets and leaving the wiring patterns and the bumps on the electrically insulating substrate so as to transfer them.

According to the above process, a wiring board as shown in FIG. 2 is obtained as described later.

In one embodiment of the above mentioned production process, upon embedding the spherical semiconductor element, a portion of the spherical semiconductor element may be exposed on each side of the main surface of the prepreg substrate, and an exposed portion of the wiring on the surface of the spherical semiconductor element may have a terminal electrode which is to be connected to the wiring pattern.

In the above mentioned production process, the hole through the transfer material is produced by removing a region where no wiring pattern is present. By thus forming the transfer material, it may be superimposed on and press-bonded to the prepreg substrate in place even though a portion of the spherical semiconductor element is not embedded in but exposed from the prepreg substrate. Further, when a manner which allows isotropic pressure application, for example using a pressure oven, is employed, a predetermined pressure is applied to the transfer material, which makes the transfer easier. In the production process, since the spherical semiconductor element is exposed from the prepreg substrate, designing flexibility as to the bump formation including increase of the bump number is conveniently improved.

The above mentioned wiring board according to the present invention can be produced by a process of producing a wiring board comprising the steps of:

(3-a) embedding at least a portion of a spherical semiconductor element (preferably at least half of the see, and more preferably most of the spherical semiconductor element, for example substantially the whole of the spherical semiconductor element based on its volume) in a prepreg substrate (preferably in the form of a sheet) which is made of a curable resin composition in its uncured condition, and also embedding a passive element (preferably in the chip form) having terminal electrodes at its both ends respectively;

(3-b) forming respectively, on carrier sheets, bumps and conductive thin layers as well as wiring patterns which are to be connected through a portion of the wiring of the spherical semiconductor element which portion is exposed so as to obtain an upper wiring pattern transfer material and a lower wiring pattern transfer material;

(3-c) locating and aligning each of the above mentioned wiring pattern transfer materials, through a resin sheet in its uncured condition (provided that a hole is formed through a region of the resin sheet which region is to face the conductive thin layer when the transfer material is so located and aligned), on each side of the prepreg substrate in which the spherical semiconductor element is embedded while the conductive thin layers are located on the terminal electrodes of the passive element, followed by heating with pressing them so as to integrally bond them, whereby the prepreg substrate and the uncured resin sheets are made into an electrically insulating substrate while the wiring patterns are connected to each other with the wiring of the spherical semiconductor element; and

(3-d) removing the carrier sheets and leaving the wiring patterns and the bumps on the electrically insulating substrate so as to transfer them.

According to the above process, a wiring board as shown in FIG. 3 is obtained as described later. It is noted that the conductive thin layer formed in a region of the wiring pattern which region is to be connected to the passive element, and such formation of the thin layer may be carried out by for example printing of a conductive adhesive.

With the above production process, when a portion of the spherical semiconductor element is not embedded but exposed from the prepreg substrate in the step (3-a), the transfer material which is formed in the step (3-b) and which is placed on the side where the spherical semiconductor element is exposed in the step (3-c) comprises the carrier sheet having a hole through the sheet, and also similarly to the above, the resin sheet has a hole in the sheet through which hole the exposed portion of the spherical semiconductor element as far as the resin sheet is placed on the side where the spherical semiconductor element is exposed.

According to the above production process, the terminal electrodes of the embedded passive element are readily connected to the wiring patterns by the provision of the conductive thin layer to the transfer material which layer is made of for example an anisotropic conductive film (ACF) or a conductive adhesive or the like. In order to achieve the flip chip connection through the bump and the connection with the terminal electrode of the passive element, it is preferable that a region of the uncured resin sheet is selectively removed which region corresponds to the conductive thin layer.

The wiring board according to the present invention can be produced by a process of producing a wiring board in which a spherical semiconductor element is used, comprising the steps of:

(4-A) providing the spherical semiconductor element having a wiring on its surface;

(4-B) embedding a passive element in the form of a chip having a terminal electrode at its each end in each prepreg substrate which is made of a curable resin composition in its uncured condition, so that a part embedded upper prepreg substrate and a part embedded lower prepreg substrate are obtained;

(4-C) forming a cavity (or a space) in a predetermined position in each of the part embedded upper prepreg substrate and the part embedded lower prepreg substrate;

(4-D) forming respectively, on carrier sheets, conductive thin layers and wiring patterns which are to be connected to each other by the wiring of the spherical semiconductor element, so that an upper transfer material and a lower transfer material are obtained;

(4-E) locating a resin sheet in its uncured condition in at least one of a space between the part embedded upper prepreg substrate and the part embedded lower prepreg substrate, a space between the part embedded upper prepreg substrate and the upper transfer material and a space between the part embedded lower prepreg substrate and the lower transfer sheet, and also locating the spherical semiconductor element between the part embedded upper prepreg substrate and the part embedded lower prepreg substrate, followed by aligning all of them;

(4-F) heating so as to bond the transfer sheets, the prepreg substrate, and the resin sheets while pressing them together so as to make the prepreg substrate and the resin sheets into an electrically insulating substrate while connecting the passive element to the wiring of the spherical semiconductor element; and

(4-G) removing the carrier sheets and leaving the wiring patterns and the bumps on the electrically insulating substrate so as to transfer them.

According to the above process, a wiring board as shown in FIG. 4 is obtained as described later.

The prepreg substrate which is used in the step (4-B) may optionally has a through hole formed in place which is filled with a conductive paste. The embedment of the passive element is preferably carried out such that the terminal electrodes are located on the both sides of the prepreg substrate (that is, the terminal electrodes are located on the main surfaces on the both sides of the prepreg substrate). In this case, the conductive paste becomes a via hole conductor through heating while pressing in the step (4-F), and such via hole conductor can connect to the passive element contained in the other prepreg substrate.

The cavities formed in the step (4-C) optionally deforms upon heating while pressing in the step (4-F) so that they can house the spherical semiconductor element.

In the step (4-D), a bump may be formed on the wiring pattern if necessary, so that the wiring of the spherical semiconductor element is connected to the wiring pattern through the bump (that is, “directly” connected in the meaning of the present description) upon heating while pressing in the step (4-F). Similarly to the above, the conductive thin layer may be formed by for example printing of a conductive adhesive on a region of the wiring pattern to which the passive element is to be connected.

In the step (4-E), when there is the resin sheet between the part embedded upper prepreg substrate and the part embedded lower prepreg substrate upon locating the spherical semiconductor element, the spherical semiconductor element is placed on the upper side or the lower side of the resin sheet, and the resin sheet has a hole through which the spherical semiconductor element can pass and also a hole in its region which corresponds to the passive element embedded in the part embedded prepreg substrate. Further, when the resin sheet is located in space between the part embedded upper prepreg substrate and the upper transfer material and/or the space between the part embedded lower prepreg substrate and the lower transfer sheet, the resin sheet has a through hole in a region which faces the thin conductive layer which is formed on the transfer material.

When the prepreg substrate which is formed in the step (4-B) has a through hole which is filled with the conductive paste, the resin sheet which faces such prepreg substrate upon the alignment of them has a through hole which corresponds to the through hole of the prepreg substrate. Such through hole of the resin sheet may optionally be filled with a conductive paste. In such case, upon heating with pressing in the step (4-F), the conductive paste of the prepreg substrate becomes a via hole conductor, which is connected to the passive element and/or the wiring pattern. It is noted that when the through hole of the resin sheet contains the conductive paste, the connection is achieved through such conductive paste.

According to the above mentioned production process of the wiring board, since the electric connection can be carried out as predetermined along a horizontal direction of the wiring board, the flexibility of designing the wiring board is greatly improved. Further, the passive elements in the form of the chips may be connected continuously and horizontally via the conductive thin layer(s). Therefore, the number of the combination types of the embedded passive can be considerably increased.

A portion of the wiring board according to the present invention is preferably flexible. In other embodiment, substantially the whole of the wiring board according to the present invention is preferably flexible. The term “flexible” in the present description means a property which allows the formation of a curved region in a portion or a whole of the wiring board when a force is applied to the wiring board which is spreading two-dimensionally in its original form (i.e. under the condition without any applied force). Such formation of the curved region is preferably into any arbitrary form and/or along any arbitrary direction. By appropriately selecting a material which forms the electrically insulating substrate, such flexibility can be provided to the wiring board. In addition, the flexibility of the wiring board can be controlled by a rigidizing element present in the electrically insulating substrate as explained later.

In order to provide the flexibility to substantially the whole of the wiring board, a curable resin which is a main component forming the electrically insulating substrate and which becomes flexible after being cured is used. Such resin which exhibits the flexibility may be selected based on an intended flexibility from a polyimide resin, a wholly aromatic polyamide resin, an epoxy resin, a phenol resin, a wholly aromatic polyester resin, an aniline resin, a polydiphenyl ether resin, a polyurethane resin, a urea resin, a melamine resin, a xylene resin, a diallyl phthalate resin, a phthalic resin, a fluororesin, a liquid crystal polymer, PET (polyethylene terephthalate), PEN (polyethylene naphthalate) and the like. Depending on the properties of the spherical semiconductor element to be used, appropriately blending with such resin as a main component which forms the electrically insulating substrate can provide with the wiring board which has an improved high frequency property and also different flexibility. It is noted that the epoxy resin is preferable from viewpoints of its heat resistance and adhesive property, and that the polyimide resin may be used so as to provide with more sufficient flexibility.

In other embodiment, an elastomer is used in place of or in addition to using the curable resin which shows the flexibility after being cured. In the latter embodiment, the elastomer is added to such curable resin, and the curable resin itself does not have to be so flexible after being cured. As such elastomer, a block copolymer of styrene and butadiene, a polymer produced by hydrogenating a double bond of such copolymer, and a hydrogenated styrene based thermoplastic elastomer are exemplified. The addition of the elastomer leads not only to the provision of the flexibility but also to the improvement in its weather resistance, heat resistance, chemical resistance against for example acids and alkalis.

By selecting an amount of the elastomer to be added, the electrically insulating substrate and thus the wiring board can have a desired elastic modulus. Generally, an amount of the elastomer to be added is preferably in the range between 5% by weight and 30% by weight to an amount of the resin(s) which forms the electrically insulating substrate expect the elastomer.

The material which forms the electrically insulating substrate may contain a filler of an inorganic material such as alumina, silica, aluminum nitride, boron nitride, magnesium oxide or the like, which provides with an improved heat radiation property and further an improved high frequency property. Such inorganic filler in the form of fine particles may be surface-treated with a saturated or unsaturated fatty acid such as stearic acid, oleic acid or linoleic acid or the like to form a coating layer around the particles, which reduces a surface area of the fine particles so that their affinity as to the resin around them is desirably increased.

It is noted that as to the flexibility of the wiring board, the thickness of the electrically insulating substrate is also important. A flexural-rigidity is proportional to a thickness of a substrate to the third power, and thus a substrate having a thickness of not larger than 500 μm is preferable since it generally has a good flexibility. However, a substrate having a larger thickness has a less flexibility, and in such case, an amount of the elastomer to be added can be increased so as to compensate the less flexibility. The amount of the elastomer to be added may be in the range between for example 30% by weight and 80% by weight. It is noted that a polyimide to which 40% of a hydrogenated styrene based thermoplastic elastomer was added was used in the example which will be described later.

In order to provide a flexibility to a portion of the wiring board, a material is which forms the electrically insulating substrate is selected such that the whole of the electrically insulating substrate has the flexibility, and then a specific region which does not require the flexibility is selectively made relatively hard (or rigidized). Such selective rigidizing is carried out by providing an element to such specific region which material is more rigid relative to the material around such region. As such relatively rigid element, various electronic elements (for example, an IC element for the formation of an electronic circuit, an electric connection element for a wiring pattern, an electronic part and the like) and various insulator elements are exemplified. By providing such relatively rigid element to a specific region, the flexibility of the electrically insulating substrate can be controlled. Appropriate selection of the kind and the number of the relatively rigid elements can provide a desired flexibility. Particularly, an electrically insulating material in the form of particles or balls (which are larger than the particles) are preferably used. Concretely, for example the electrically insulating material in the form of spheres having various diameters may be used. The arrangement of such rigid elements may be carried out by pressing the element into a material which forms the electrically insulating substrate while it is heated to be softened.

Further, the wiring board according to the present invention preferably has a plurality of notches in its periphery. For arranging the wiring board in a housing of an electronic device, ribs are formed inside the housing so that they can be fitted into the notches. By such fitting, the wiring board can be held in the housing in place, so that connecting elements such as bosses, screws and the like can be reduced which are required for secure the wiring board in the housing. Further, a broader wiring board can be provided which effectively uses an area inside the housing.

By mounting the wiring board according to the present invention, further advanced function and further thinning of the electronic device can be achieved. Thus, the present invention also provides electronic devices which comprise the various wiring boards respectively.

According to the present invention, by embedding the spherical semiconductor element in the electrically insulating substrate, the wiring board is provided in which the wiring patterns are connected in their high density. Particularly, when the wiring board is formed with at least one, and preferably plural spherical semiconductor elements embedded in the electrically insulating substrate, a high density electronic circuit can be formed in the electrically insulating substrate.

Further, by providing with the flexibility while making a predetermined region rigidized, a required flexibility can be provided to a specific region of the wiring board. As a result, the wiring board can be housed in a housing of for example a mobile phone while its form follows inner profile of the housing. That is, the wiring board can be contained in the housing without formation of a useless space in the housing, which is convenient for the miniaturizing and thinning of the electronic device.

### BRIEF DESCRIPTION OF DRAWINGS

FIG. 1 schematically shows a cross sectional view of a wiring board of the first embodiment according to the present invention;

FIG. 2 schematically shows a cross sectional view of a wiring board of another first embodiment according to the present invention;

FIG. 3 schematically shows a cross sectional view of a wiring board of the second embodiment according to the present invention;

FIG. 4 schematically shows a cross sectional view of a wiring board of the third embodiment according to the present invention;

FIG. 5 schematically shows a cross sectional view of a wiring board according to the present invention in which an inner via hole is formed through each layer;

FIG. 6 schematically shows a cross sectional view of a wiring board according to the present invention which forms a multilayer wiring board;

FIG. 7 schematically shows in cross sectional views steps of one embodiment of a process of produce a wiring board of the first embodiment according to the present invention (which process corresponds to the fourth embodiment according to the present invention);

FIG. 8 schematically shows another embodiment of a process of produce a wiring board of the first embodiment according to the present invention (which process corresponds to the fifth embodiment according to the present invention;

FIG. 9 schematically shows another embodiment of a process of produce a wiring board of the second embodiment according to the present invention (which process corresponds to the sixth embodiment according to the present invention;

FIG. 10 schematically shows another embodiment of a process of produce a wiring board of the third embodiment according to the present invention (which process corresponds to the seventh embodiment according to the present invention;

FIG. 11 schematically shows a cross sectional view of a wiring board of the eighth embodiment according to the present invention;

FIG. 12 schematically shows a cross sectional view of a wiring board of the ninth embodiment according to the present invention;

FIG. 13 schematically shows a cross sectional view of a wiring board of the tenth embodiment according to the present invention;

FIG. 14 schematically shows a cross sectional view of a wiring board of the eleventh embodiment according to the present invention;

FIG. 15 schematically shows a cross sectional view of a wiring board of the twelfth embodiment according to the present invention;

FIG. 16 schematically shows a cross sectional view of a wiring board of the thirteenth embodiment according to the present invention;

FIG. 17 schematically shows a cross sectional view of a wiring board of the fourteenth embodiment according to the present invention;

FIG. 18 schematically shows a cross sectional view of a wiring board of the fifteenth embodiment according to the present invention;

FIG. 19 schematically shows a cross sectional view of a wiring board of the sixteenth embodiment according to the present invention;

FIGS. 20(a) to 20(f) schematically show in cross sectional views steps of one embodiment of a process of produce a wiring board of the first embodiment according to the present invention;

FIGS. 21(a) to 21(e) schematically show in cross sectional views steps of one embodiment of a process of produce a wiring board of the first embodiment according to the present invention;

FIGS. 22(a) to 22(c) schematically show in cross sectional views steps of one embodiment of a process of produce a wiring board of the first embodiment according to the present invention;

FIGS. 23(a) to 23(c) schematically show in cross sectional views steps of one embodiment of a process of produce a wiring board of the first embodiment according to the present invention;

FIGS. 24(a) to 24(b) schematically show in cross sectional views steps of one embodiment of a process of produce a wiring board of the first embodiment according to the present invention;

FIG. 25(a) schematically shows a cross sectional view of a spherical semiconductor element which is used in an electronic device in the seventeenth embodiment according to the present invention, and FIG. 25(b) shows a circuit block diagram of such electronic device;

FIG. 26(a) schematically shows a side view of a spherical semiconductor element which is used for an electronic device in the eighteenth embodiment according to the present invention, FIG. 25(b) schematically shows a cross sectional view along a line A-A in FIG. 26(a), FIG. 26(c) schematically shows a plane view of a wiring board having an embedded spherical semiconductor element which is used for an electronic device, FIG. 26(d) schematically shows a plane view of other wiring board having an embedded spherical semiconductor element which is used for an electronic device, and FIG. 26(e) schematically shows a side view of a wiring board having an embedded spherical semiconductor element which is deformed into a form contained in an electronic device;

FIGS. 27(a) to FIG. 27(e) schematically show views which explain a conventional mobile phone and a configuration of a printed wiring board which is used for such phone;

FIG. 28 schematically shows a perspective view of a conventional wiring board in which a spherical semiconductor element is mounted onto a surface of the wiring board;

FIG. 29 schematically shows a perspective view of a conventional wiring board in which spherical semiconductor elements are linked horizontally on a surface of the wiring board;

FIG. 30 schematically shows a wiring board which has a usual plate type semiconductor element which is embedded therein.

### EMBODIMENTS FOR CARRYING OUT THE INVENTION

The present invention will be explained with reference to the drawings. It is noted that the present invention is not limited to the embodiments described later. For example, the below embodiments may be combined variously.

### First Embodiment

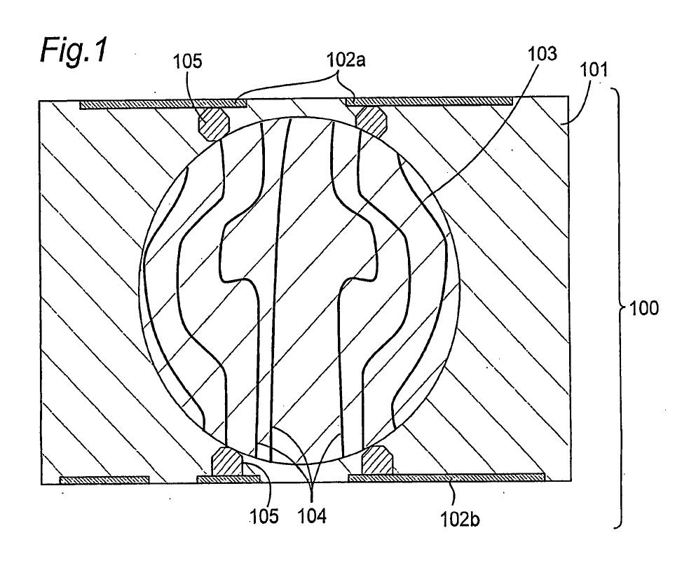

The first embodiment is an example of a wiring board according to the present invention which comprises a spherical semiconductor element, which is shown in a schematic cross sectional view in FIG. 1.

As shown in FIG. 1, the wiring board 100 comprises an electrically insulating substrate 101, a wiring pattern 102a which is formed on one main surface of the electrically insulating substrate 101, a wiring pattern 102b which is formed on the other main surface of the electrically insulating substrate 101, and a spherical semiconductor element 103 which is embedded in the inside of the electrically insulating substrate 101. The wiring patterns 102a and 102b are electrically connected through wirings 104 which are formed on the spherical semiconductor element as well as bumps 105 which are formed on terminal electrodes (not shown) of the wirings. In the shown embodiment, the wiring patterns and the wirings are electrically connected directly.

The electrically insulating substrate 101 is made of a rein composition of which main component is a resin. When it is to be made of a transparent resin depending on its application, an acrylic resin, a polycarbonate resin, a polystyrene resin, an AS resin, an epoxy resin and the like which have a high transparency and a good formability are desirable as the transparent resin, which is not limited to those. When the electrically insulating substrate is not required to be transparent, it is desirably made of a mixture which contains an inorganic filler and a thermosetting resin. For the inorganic filler, for example, Al₂O₃, MgO, BN, AlN or SiO₂ may be used. The inorganic filler is desirably contained highly densely in an amount between 70% by weight and 95% by weight based on the total of the composition (which includes the inorganic filler). For example, when SiO₂ is loaded highly densely as the inorganic filler up to not smaller than 80% by weight for the purpose of a low dielectric substrate, a thermal conductivity of at least 1 W/mK can be achieved. Further, when AlN is loaded up to 95% by weight as the inorganic filler for the purpose of a highly thermally conductive substrate, a thermal conductivity of 10 W/mK can be achieved. It is noted that an upper limit of the loaded amount of the inorganic filler is usually 95% by weight, an upper limit of the thermal conductivity is 10 W/mK. In the present invention, a technique which is disclosed in Japanese Patent Kokai Publication No. 1999-220262 related to a mixture of an inorganic filler and a thermosetting resin may be employed for an example of the electrically insulating substrate. The contents of this patent publication are incorporated herein by reference thereto in their entirety.

In the wiring board according to the present invention, an average diameter of the inorganic filler which is contained in the resin composition for the electrically insulating substrate is desirably in the range between 0.1 μm and 100 μm. The thermosetting resin is desirably for example an epoxy resin, a phenol resin, a cyanate resin or a polyphenylene ether resin which is heat resistive. The epoxy resin is particularly desirable because of its high heat resistance. It is noted that the resin composition (or mixture) may comprise a dispersing agent, a colorant, a coupling agent or a release agent.

The wiring patterns 102a and 102b are made of an electrically conductive material, for example, an etched metal foil (such a copper foil), a conductive coating of an electrically conductive resin composition or the like. When a copper foil is used for the wiring pattern, for example a copper foil having a thickness in the range between 9 μm and 35 μm which has been made of electrolytically plating. A contact surface of the copper foil which surface is to be in contact with the electrically insulating substrate 101 is desirably roughened so as to improve its adhesive property with the electrically insulating substrate 101. In addition, as the copper foil, a copper foil of which surface has been treated with a coupling agent or plated with tin, zinc or nickel may be used so as to improve its adhesive property and acid resistance. Further, as the copper foil, a copper foil of which surface has been plated with a solder of Sn—Pb alloy or a Pb free solder such as Sn—Ag—Bi may be used. The wiring pattern to be formed in the present invention is preferably prepared by a transfer manner in which a transfer material is generally used, and in such case, the wiring pattern is pressed into the electrically insulating substrate, that is, the main surface of the electrically insulating substrate is flushed with a surface of the wiring pattern as shown.

For the formation of the connection between the wiring patterns 102a and 102b and the wiring 104 of the spherical semiconductor element 103, for example a flip chip bonding manner may be used. In the embodiment shown in FIG. 1, the wirings 104 formed on the spherical semiconductor element 103 are connected to the terminal electrodes of the wiring patterns 102a and 102b through the bumps 105. It is noted that connection areas around the bumps 105 are sealed by the electrically insulating substrate 101 so that they are reinforced. It is of course possible that only the areas around the bumps 105 are formed with other electrically insulating material or sealing resin. For example, an electrically conductive resin (such as an ACF) or a solder material may be present between the bumps 105 and the terminal electrodes.

Generally, the spherical semiconductor element requires a support means which keeps it in place because of the shape of the spherical semiconductor element. However, with the configuration of the shown wiring board, embedding the spherical semiconductor element into the electrically insulating substrate automatically provides such means, so that no specific means is required.

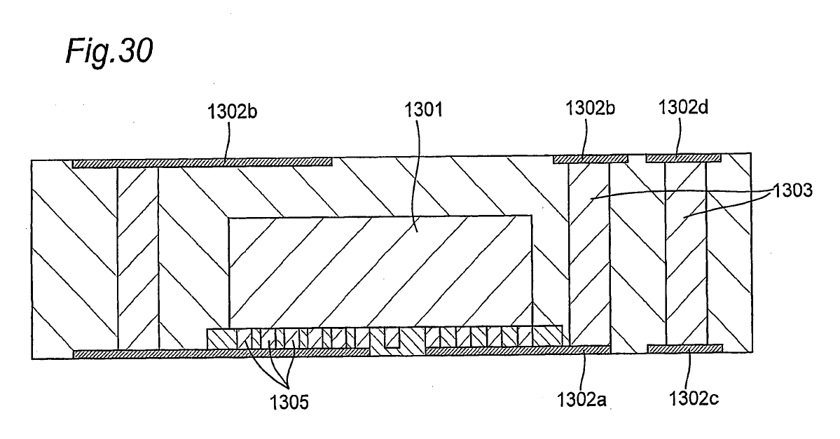

In addition, when the conventional plate type semiconductor element 130 as shown in FIG. 30 which is formed by cutting out of a wafer is embedded in a substrate, the via hole conductor 1303 is used for connecting the wiring pattern 1302a formed on one main surface of the substrate to the wiring pattern 1302b formed on the other main surface which faces to said one main surface. In such case, a via hole conductor pitch of at least about 400 μm is required, which constrains the wiring pattern designing. To the contrary, according to the present invention, the wiring patterns 102a and 102b formed on one main surface and the other main surface opposite thereto of the electrically insulating substrate respectively are electrically connected with the wiring 104 which is formed on the spherical semiconductor element, that is, the electric connection is achieved by the wiring 104 of the spherical semiconductor element which allows wiring with a smaller pitch (5 μm pitch at present), so that the connection between the wiring patterns can be carried out with highly densely wiring.

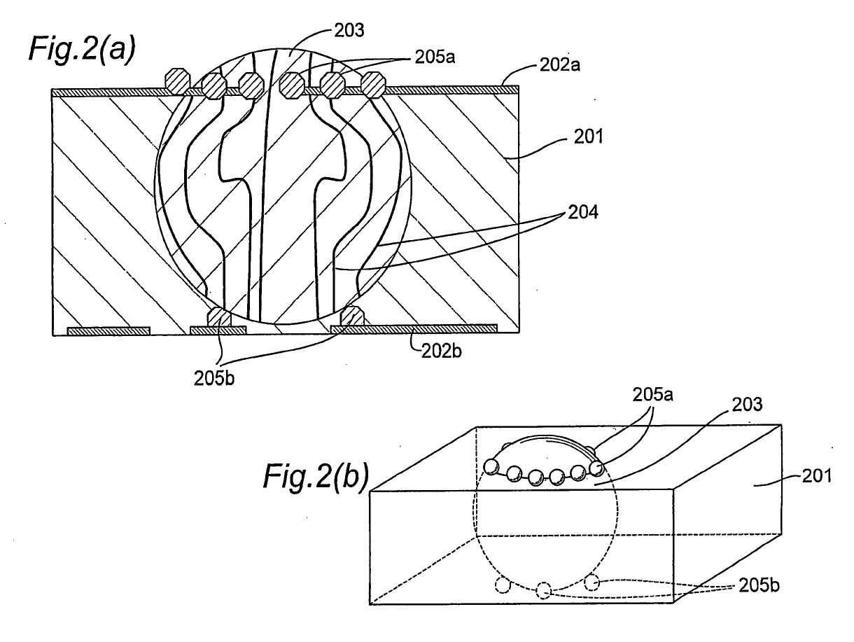

It is noted that when more bumps 105 are required for connecting the wiring patterns 102, the whole of the spherical semiconductor element 203 is fully embedded in the electrically insulating substrate 201 (that is, all of the spherical semiconductor element is not embedded), but the spherical semiconductor element is preferably embedded such that a portion a periphery of the spherical semiconductor element is exposed from the main surface of the electrically insulating substrate as shown in a schematic cross sectional view in FIG. 2(a) and also in a schematic perspective view in FIG. 2(b), so that sufficient number of the bumps can be formed on the periphery. As a result of the exposure of an upper portion of the spherical semiconductor element from the electrically insulating substrate 201 as shown in FIG. 2(b), the perimeter of the exposed potion is increased, which allows the number of the bumps 205a to be formed around the periphery to be increased compared with the case wherein the whole of the spherical semiconductor element 203 is completely embedded.

As seen from the cross sectional view shown in FIG. 2(a), increasing the number of the bumps 205a around the upper portion increases the flexibility as to design of the wiring 204 on the spherical semiconductor element 203 which connects the upper wiring pattern 202a and the lower wiring pattern 202b. It is of course possible that a portion of a lower part of the spherical semiconductor element 203 is exposed and the number of the bumps to be formed around a periphery of such portion is increased, so that the flexibility as to design is increased.

In the present embodiment, the wiring patterns 102a and 102b or 202a and 202b are both formed on the both main surfaces of the electrically insulating substrate 101 or 201 respectively (that is, corresponding to the double-sided wiring board). In other embodiment, in place of such wiring pattern, a wiring pattern which is formed on other double-sided or multilayer wiring board is connected to the wiring of the spherical semiconductor element. Such other embodiment corresponds to a situation wherein a double-sided or multilayer wiring board is placed on the wiring board shown in FIG. 1 or FIG. 2(a), and a wiring board of a lower main surface of such double-sided or multilayer wiring board is electrically connected to the spherical semiconductor element. When a double-sided or multilayer wiring board is located on the wiring board according to the present invention, the formation of wiring in a higher density becomes possible. Particularly, with the wiring board as shown in FIG. 2(a), the number of connecting points between the wiring pattern and the spherical semiconductor element can be increased, so that a high speed electronic circuit while being more compact and lighter can be formed.

In other embodiment of the wiring board according to the present invention, the electrically insulating substrate 201 may further have a wiring pattern(s) in the inside thereof, and such wiring pattern(s) is connected by means of a via hole conductor(s) and the like, so that the wiring board may have a multilayer wiring board. In this case, the wiring on the surface of the spherical semiconductor element may be connected to the inside wiring pattern, so that the formation of wiring in a higher density becomes possible, and the number of connecting points between the wiring pattern and the spherical semiconductor element can be increased.

### Second Embodiment

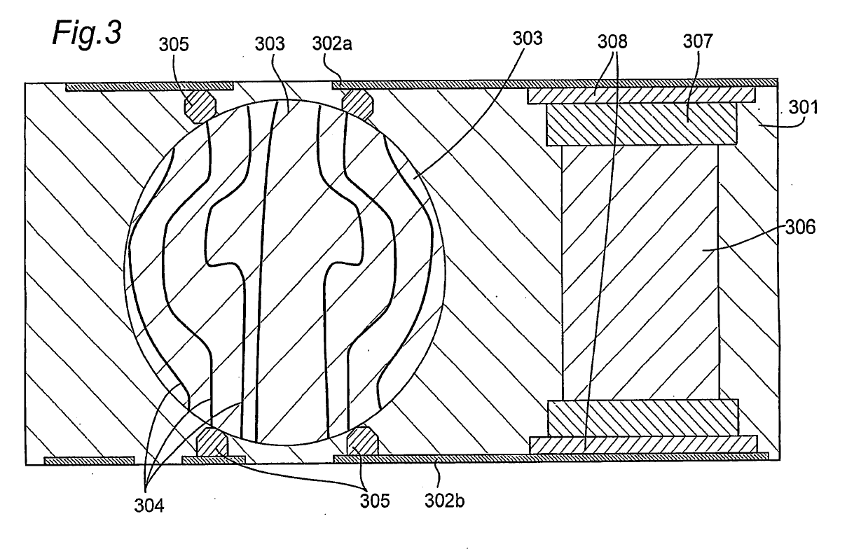

The second embodiment is one example of a wiring board according to the present invention which comprises a spherical semiconductor element and a passive element, which is shown in a schematic cross sectional view in FIG. 3. The wiring board 300 of the present embodiment corresponds to the wiring board as shown which further comprises the passive element 306, and such wiring board comprises an electrically insulating substrate 301, a wiring pattern 302a which is formed on one main surface of the electrically insulating substrate 301, a wiring pattern 302b which is formed on the other main surface of the electrically insulating substrate 301, a spherical semiconductor element 303 which is connected directly to the wiring patterns 302a and 302b, and the passive element 306.

In the present embodiment, similarly to the above mentioned embodiment, the wiring 304 of the spherical semiconductor element is connected to the bumps 305 to the wiring patterns. As to the passive element 306, its terminal electrodes 307 are connected through its adjacent conductive connections 308 to the wiring patterns 302a and 302b which are formed on the both main surfaces of the electrically insulating substrate 301.

The passive element 306 may be a general chip part (L: inductor, C: capacitor, and R: resistor), and in other embodiment, it may be a capacitative element which is a dielectric body 306 having a high dielectric constant merely sandwiched by the terminal electrodes 307. The conductive connection 308 may be made of for example an ACF, an electrically conductive adhesive or the like. In the shown embodiment, the conductive connection 308 made of the conductive adhesive connects the terminal electrode 307 and the wiring pattern 302 formed on the electrically insulating substrate 301. As a result, the spherical semiconductor element 303 and the passive element 306 are electrically connected through the wiring patterns 302.

Generally, an inductor can be provided within the spherical semiconductor element by forming a wiring pattern in the form of a coil, but it has been difficult to provide a resistor or a capacitative element. Since the spherical semiconductor element 303 can be embedded adjacent to the passive element 306 in the electrically insulating substrate 301, a system function of for example a micromini photovoltaics device such as a solar cell, a transformer device or the like can be completed in a single wiring board. Therefore, a very compact semiconductor device can be provide of which size is in the same order as that of the spherical semiconductor element 303 to be embedded and in which a system function is completed.

### Third Embodiment

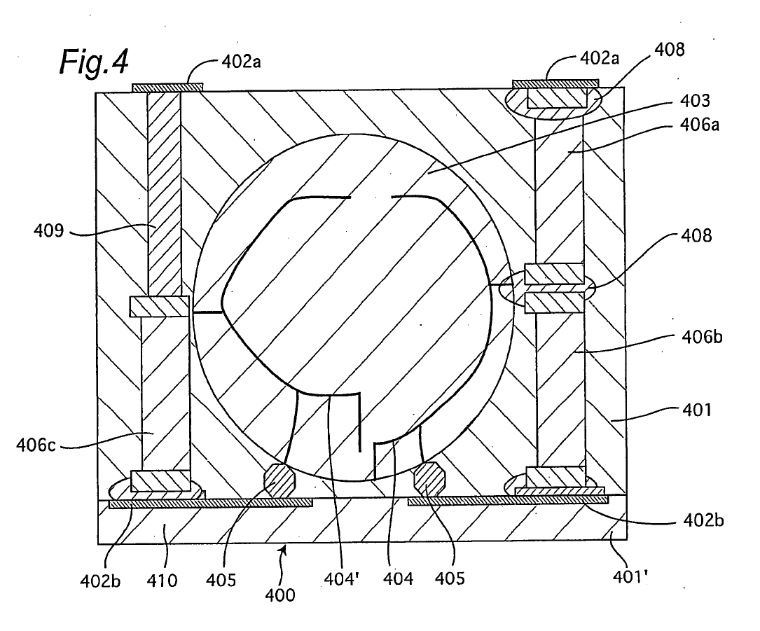

The present embodiment is one example of a wiring board according to the present invention in which a spherical semiconductor element and a plurality of passive elements, and such embodiment is schematically shown FIG. 4 in its cross sectional view.

As shown in FIG. 4, the wiring board 400 having a semiconductor device of the present invention comprises an electrically insulating substrate 401, a wiring pattern 402a which is formed on one main surface of the electrically insulating substrate 401, a wiring pattern 402b which is formed on the other main surface of the electrically insulating substrate 401, a via hole conductor 409, a spherical semiconductor element 403, a general chip parts 406a, 406b and 406c.

In the present embodiment, one terminal electrode of the chip part 406c is connected to the wiring pattern 402a through the via hole conductor 409, and the other terminal electrode is connected to the wiring pattern 402b. Further, the chip parts 406a and 406b are connected to the wiring patterns 402a and 402b respectively. In addition, the chip parts 406a and 406b are connected directly to the wiring 404 formed on the spherical semiconductor element 403 through a mass of an electrically conductive resin 408, so that the wiring 404 connects the wiring patterns 402a and 402b together with the chip parts 406 and the conductive resin 408 in the shown embodiment. That is, the wiring 404 indirectly connects the wiring patterns 402a and 402b. It is noted that other wiring 404′ of the spherical semiconductor element 403 is connected directly to the wiring pattern 402b through the bump 405, and also indirectly to the wiring pattern 402a through the chip 406c.

The via hole conductor 409 is made of for example a thermosetting and electrically conductive material. As such conductive material, for example an electrically conductive composition in which metal particles and a thermosetting resin are mixed. As the metal particles, those made of gold, silver, copper or nickel may be used. Gold, silver, copper and nickel are preferable since they are highly electrically conductive, and copper is particularly desirable since it is highly electrically conductive with a less migration property. As the thermosetting resin, an epoxy resin, a phenol resin, and a cyanate resin or a polyphenylene ether resin may be used. The epoxy resin is particularly desirable since it is highly heat resistive.

Thus, according to the present embodiment, a various passive elements 406 are formed in the electrically insulating substrate 401 in which the spherical semiconductor element 403 is embedded, so that a system function can be further improved when compared with the second embodiment. Therefore, a very compact semiconductor device can be provide of which size is in the same order as that of the spherical semiconductor element 403 to be embedded and in which a system function is completed. It is noted that the wiring board according to the present invention comprises the wiring board on each of the main surfaces of the electrically insulating substrate 401, but in the shown embodiment, the lower wiring pattern 402b located on the lower main surface of the electrically insulating substrate 401 further contains an electrically insulating substrate 401′ below it. In this case, the wiring pattern 402b is not exposed.

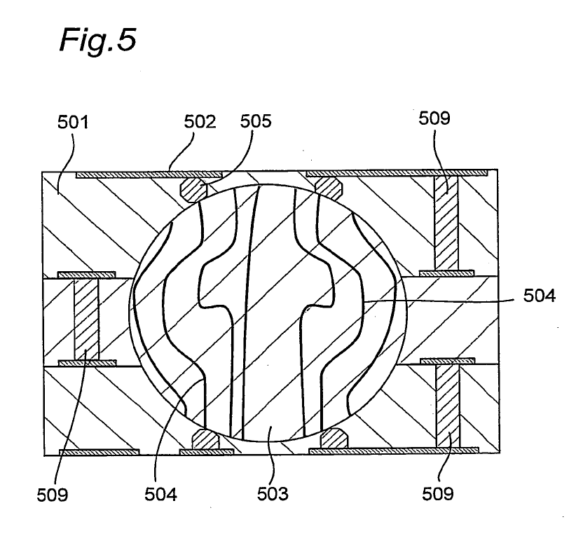

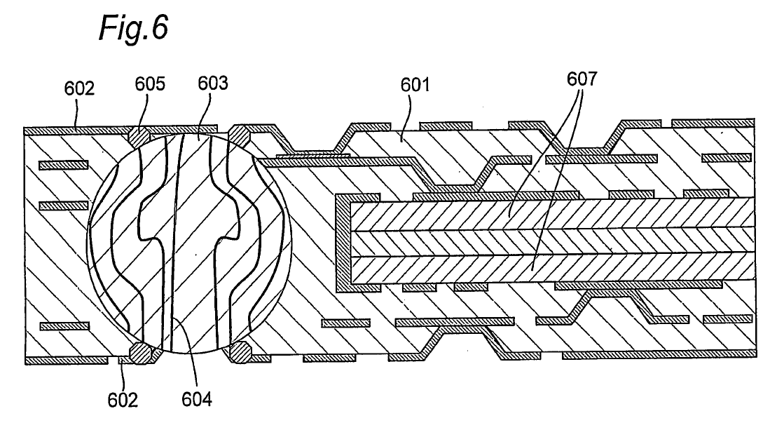

It is noted as shown in FIG. 5 or FIG. 6 that a double layer or multilayer wiring pattern may be formed in the electrically insulating substrate 501 or 601 which contains the wiring patterns 502 or 602 and the spherical semiconductor element 503 or 603 in the wiring board. Further it is noted that the wiring patterns 502 or 602 are directly to the wiring 504 or 604 of the spherical semiconductor element through the bumps 505 or 605. As a result, the wiring board according to the present invention forms a multilayer wiring board. Therefore, the electrically insulating substrate may have an additional wiring pattern(s) in its inside. In this case, the wiring pattern(s) in the inside and the wiring patterns on the surfaces are connected as predetermined by the via hole conductors 509. (It is noted that via hole conductors are not shown in FIG. 6.)

It is noted that as shown in FIG. 6, a plurality of the wiring patters located inside may be formed by the build-up manner, and a capacitor part 607 may be formed by sandwiching a dielectric layer between the wiring patterns. As clearly seen, in the wiring board according to the present invention which comprises the electrically insulating substrate having the spherical semiconductor element embedded therein, there is no particular limitation as to the number of the wiring board and the formation of the passive element, so that a function which has not been hitherto provided can be provided.

It is noted that when an electrically insulating substrate which contains an inorganic filler is used in the wiring board according to the present invention, heat generated in a circuit part is rapidly transported so that a highly reliable wiring board in which the spherical semiconductor element is used can be provided. Further, a linear expansion coefficient, a thermal conductivity, a dielectric constant and the like are readily controlled through the selection of the inorganic filler used in the electrically insulating substrate. Particularly, when the linear expansion coefficient of the electrically insulating substrate is made close to that of the spherical semiconductor element, for example occurrence of cracking because of the temperature change can be prevented, so that a highly reliable circuit module can be realized. Further, when the thermal conductivity of the electrically insulating substrate is improved, a semiconductor element containing wiring board having a high reliability can be provided even when circuit parts are mounted in a high density. In addition, lowering the dielectric constant of the electrically insulating substrate leads to a module for high frequency circuit which has a less dielectric loss.

Also, when the spherical semiconductor element is fully embedded in the electrically insulating substrate, the spherical semiconductor element, the circuit parts and the like are completely sealed from the ambient air by the material which forms the electrically insulating substrate, so that degradation of the reliability of the wiring board due to the moisture can be prevented.

### Fourth Embodiment

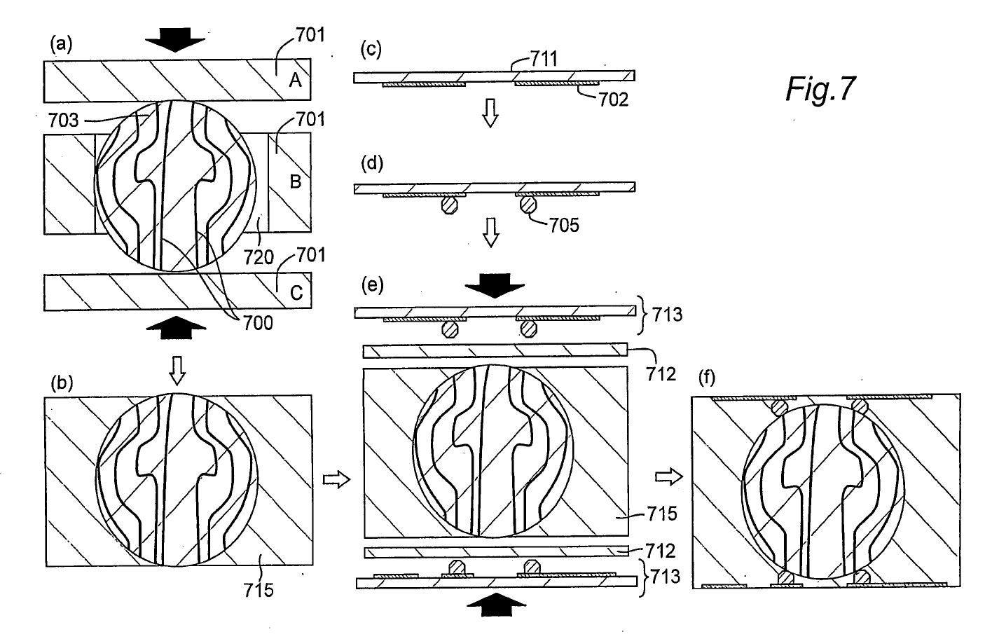

The present embodiment is one example of a process of producing the wiring board according to the first embodiment, and sequential steps of such process are schematically shown in FIG. 7 in cross sectional views.

First, a spherical semiconductor element 703 is prepared which has on its surface wirings 700 which have terminal electrodes at their ends. It is noted that each of the wirings 700 is formed such that it connects a predetermined upper point and a predetermined lower point of the surface of the spherical semiconductor element. On the other hand, prepreg substrates 701A, 701B and 701C in their prepreg condition (that is, in an uncured or semi-cured condition) are prepared as shown in FIG. 7(a) using a resin composition comprising a curable resin which may further comprise an inorganic filler such as silica or the like depending on its application.

As the prepreg substrate 701B, a resin sheet is prepared having a through hole 720 which has a diameter substantially the same as or larger a little than that of the spherical semiconductor element 703 and also having a thickness which is substantially the same as or larger or smaller a little than a diameter of the spherical semiconductor element. Further, as the prepreg substrates 701A and 701C, resin sheets are prepared which function as cushions upon the application of a pressure downward or upward so as to embedding the spherical semiconductor element. Then, the spherical semiconductor element 703 is placed in the through hole 720 of the resin sheet 701B which is sandwiched by and aligned with the resin sheets 701A and 701C, followed by heating with pressing so as to carry out embedding the spherical semiconductor element as shown in FIG. 7(b), so that a prepreg substrate (in its uncured condition) in which the spherical semiconductor element is embedded is obtained.

The temperature and the pressure upon the above embedding depend on the kind of the resin. In the case of a prepreg substrate which is made of a thermosetting epoxy resin (of which Tg is about 180° C.), for example embedding can be carried out at 120° C. under a pressure of about 3 MPa. It is noted that upon heating with pressing, a gapping tool which controls a thickness direction dimension is preferably used for pressing. In this case, the gap thickness is larger than a thickness of the spherical semiconductor element a little.

Then, the wiring pattern 702 is formed on a carrier sheet 711 which pattern is to be connected to the wiring 700 of the spherical semiconductor element 703 as shown in FIG. 7(c), and bumps 705 are formed on the wiring pattern 702 as shown in FIG. 7(d), whereby a transfer material 713 is obtained. The bumps are preferably made of gold from a viewpoint of the connection between the spherical semiconductor element and the terminal electrode. Such transfer materials are prepared for the upper side and the lower side of the prepreg substrate respectively in which the spherical semiconductor element is embedded.

Thereafter, the prepreg substrate 715 in the uncured condition with the embedded spherical semiconductor element 703 and the transfer material 713 are aligned such that a uncured resin sheet 712 is located between the prepreg substrate 715 and the transfer material 713 on each side of the prepreg substrate 715 as shown in FIG. 7(e), followed by heating with pressing so that the prepreg substrate and the resin sheets are made into an integrated electrically insulating substrate in which the spherical semiconductor element is embedded. Then, as shown in FIG. 7(f), by removing the carrier films 711 and leaving the wiring patterns 702 and the bumps 705 so as to transfer them, the wiring board according to the present invention is obtained. The transfer of the wiring patterns and the flip chip connecting via the bumps can be carried out well under a pressure of for example about 3 MPa. The uncured resin sheet (or a dummy sheet) 712 relaxes the pressure which applied to the bumps, and also improves the transfer of the wiring patterns and the adhesion between the wiring patterns and the electrically insulating substrate having the embedded spherical semiconductor element.

According to the above mentioned production process, the bumps 705 which connect the wiring patterns 702 and the wirings 700 of the spherical semiconductor element 703 can be on the transfer material 713, which makes it easy to produce the wiring board according to the present invention, and also improves the flexibility upon designing the wiring board. By providing the uncured resin sheet between the transfer material 713 and the prepreg substrate 715 in which the spherical semiconductor element is embedded, the wiring patterns 702 are readily connected to the wiring 700 of the spherical semiconductor element through the bumps 705 similarly to the flip chip mounting using a general NCF. It is noted that the bumps 705 are provided on the spherical semiconductor element beforehand, and the transfer material without a bump may be used for transferring the wiring patterns 702.

### Fifth Embodiment

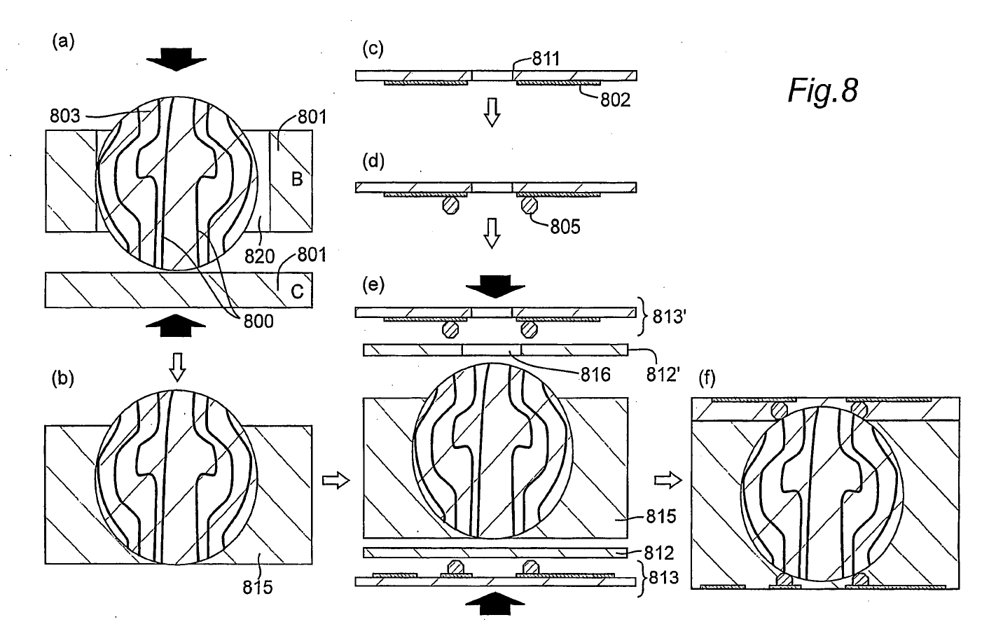

The present embodiment is one example of a process of producing a wiring board according to the present invention in which a portion of the spherical semiconductor element is not embedded, and sequential steps of such process are schematically shown in FIG. 8 in cross sectional views.

First, similarly to the embodiment shown in FIG. 7(a), and also shown in FIG. 8(a), a spherical semiconductor element 803 is prepared which has on its surface wirings 800 which have terminal electrodes at their ends, and prepreg substrates 801B and 801C in their prepreg condition (that is, in an uncured or semi-cured condition) are prepared using a resin composition comprising a curable resin. It is noted that a thickness of the prepreg substrate 801B is smaller than the diameter of the spherical semiconductor element, so that when the spherical semiconductor element is embedded in the prepreg substrate, a portion of the spherical semiconductor element is exposed above the surface of the prepreg substrate.

Then, the spherical semiconductor element 803 is located in a through hole 820 of the resin sheet 801B, and the resin sheet 801C is placed below and aligned with the resin sheet 801B as shown in FIG. 8(a), followed by heating with pressing so as to embed the spherical semiconductor element as shown in FIG. 8(b), whereby a prepreg substrate 815 (in its uncured condition) in which the spherical semiconductor element is partly embedded. It is noted that generally at least half of the spherical semiconductor element based on its volume is embedded.

When an element such as the spherical semiconductor element of which final form is not a plate is embedded as described above, using a pressure oven so as to achieve a high temperature and high pressure condition (for example, 150° C. and 100 atm) leads to isotropic pressure application, so that a portion of the spherical semiconductor element can be embedded in the resin substrate sheet 801.

Thereafter, as shown in FIG. 8(c) and FIG. 8(d) or similarly to the fourth embodiment, the transfer materials 813 and 813′ are prepared which comprise the wiring patterns 802 and the bumps 805 respectively. The difference from the transfer materials 713 is that the transfer material 813′ which is to be located above has a through hole 811 in a region where the wiring pattern 802 is not present, so that a portion of the spherical semiconductor element 803 can pass through such hole.

Then, as shown in FIG. 8(e), the transfer material 813′ is placed above the uncured resin substrate 815 (which may optionally be in a fully cured condition) in which the spherical semiconductor element 803 is embedded, also the transfer material 813 is placed below such substrate 815, and further uncured resin sheets 812 and 812′ are placed such that they intervene similarly to FIG. 7(e), and then heating at a high temperature with pressing under a high pressure so as to bond them, whereby the prepreg substrate and the resin sheets are made into an integrated electrically insulating substrate in which the spherical semiconductor element is embedded. Thereafter, as shown in FIG. 8(f), removing the carrier films 811 and leaving the wiring patterns 802 and the bumps 805 so as to transfer them, whereby the wiring board according to the present invention is obtained. It is noted that the resin sheet 812′ has a hole 816 through which a portion of the spherical semiconductor element is can pass.

Also, a high pressure at a high temperature is required to be applied to a non-plate form element in this process, and it is therefore preferable to use for example a pressure oven so as to apply a pressure isotropically. As a result, a semiconductor device is produced in which a portion of the spherical semiconductor element is exposed.

According to the above mentioned process, by removing a portion of the carrier film in the transfer material 813′ in which portion no wiring pattern is present, the transfer material 813′ can be aligned with the prepreg substrate 815 as predetermined even with using such prepreg substrate in which the spherical semiconductor element is not completely embedded and a portion thereof is exposed. Further, using a manner which applies a pressure isotropically, for example using a pressure oven leads to even pressure application to the transfer materials as predetermined, which makes transferring easy. With the above mentioned production process, the designing flexibility of the bump formation including increase the number of the bumps to be formed is further improved, which is preferable.

### Sixth Embodiment

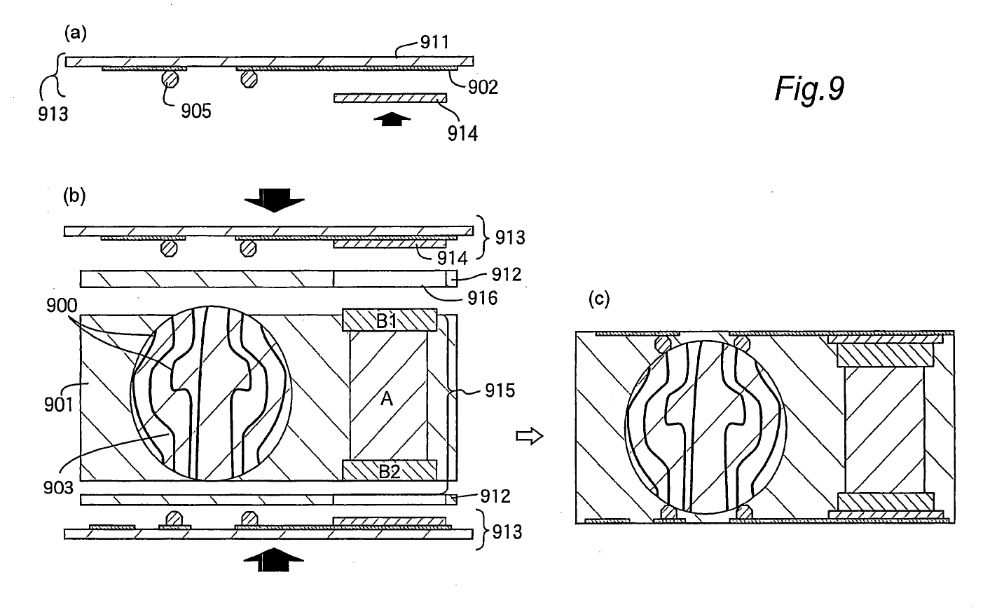

The present embodiment is one example of a process of producing a wiring board of the second embodiment shown in FIG. 3, and sequential steps of such process are schematically shown in FIG. 9 in cross sectional views.

In this embodiment, the step of embedding into the prepreg substrate 901 the spherical semiconductor element 903 on which the wirings 900 which are connected to the bumps 905 is the same as that of the above mentioned embodiment, and therefore the explanation of such step is omitted.

On one hand, the wiring board in FIG. 3 is characterized in that together with the spherical semiconductor element 903 and the passive element such as a resistor R, a capacitor C, inductor L or the like are embedded in the electrically insulating substrate 901. Basically, the passive element to be embedded is at least one of L, R and C, and the explanation herein is made with reference to a capacitor 915 as an example. The capacitor 915 is composed of a high dielectric portion 915A and terminal electrodes 915B1 and 915B2. It is of course possible that the capacitor 915 may be a general chip capacitor of which size is so-called 1608, 1005, 0603 or the like. Upon embedding the passive element 915, any appropriate manner may be employed. For example, a manner may be used in which a protective film is applied onto each of the terminal electrodes 915B1 and 915B2, then the prepreg substrate is heated so as to soften it (such that it is not fully cured, and preferably no curing proceeds), and then the passive element 915 is pressed into the substrate, followed by removing the protective films. As a result, the prepreg substrate 901 as shown in FIG. 9(b) is provided in which the spherical semiconductor element 903 and the passive element 915 are embedded.

Then, transfer materials 913 are prepared. Similarly to the above explanations, the wiring patterns 902 which are to be connected by the wirings of the spherical semiconductor element and optionally the bumps 905 are formed on the carrier films 911. The wiring patterns are to be connected also to a passive element through conductive thin layers. Therefore, the conductive thin layer 914 which is to be connected to the terminal electrode 915B1 or 915B2 of the passive element 915 is formed on a predetermined region of the wiring pattern 902, so that the transfer material 913 is prepared. Thus, the wiring patterns 902 and the terminal electrodes 915B1 and 915B2 are connected through the conductive thin layers 914. The conductive thin layers are made of for example a conductive resin. Concretely, the conductive thin layers may be formed by printing using a conductive resin mixed with metal powder, but ACF used upon flip chip mounting may be employed. In the present embodiment, the above mentioned transfer materials 913 are prepared for using above and below the prepreg substrate 901 respectively.

As shown in FIG. 9(b), the prepreg substrate 901 in its uncured condition which comprises the spherical semiconductor element 903 and the passive element 915 embedded therein, and the transfer materials 913 are aligned such that each of uncured resin sheets 912 in which a through hole 916 is formed beforehand in a region corresponding to the conductive thin layer 914 is located between the substrate and each of the transfer materials, and they are press-bonded at a high temperature and under a high pressure, so that the prepreg substrate and the resin sheets are made into an electrically insulating substrate in which the spherical semiconductor element and the passive element are embedded and the wiring patterns 902 are connected by the wirings 903 while wiring patterns 902 and the passive element 915 are connected through the conductive thin layers 914.

Thereafter, the carrier films 911 are removed so that the wiring patterns 902 and the bumps 905 are left so as to transfer them, whereby the wiring board as shown in FIG. 9(c) is obtained.

According to the above mentioned production process, by forming the conductive thin layer using the ACF or the conductive resin such as a conductive adhesive, the terminal electrode of the embedded passive element can be readily connected to the wiring pattern. It is noted that in order to make both of the flip chip connection through the bump 905 of the wiring pattern and the connection to the terminal electrode of the passive element 915 possible while using the wiring pattern of the transfer material, it is preferable that a portion 916 of the resin sheet 912 is removed which portion corresponds to the conductive thin layer 914.

### Seventh Embodiment

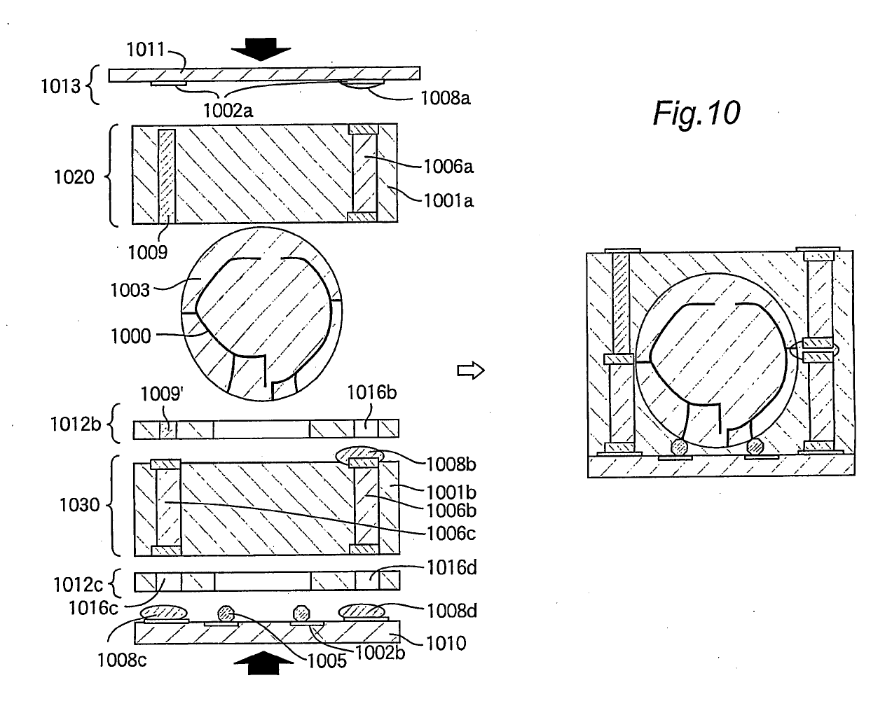

The present embodiment is one example of a process of producing a wiring board of the third embodiment shown in FIG. 4, and sequential steps of such process are schematically shown in FIG. 10 in cross sectional views.

First, a spherical semiconductor element 1003 is prepared which has a wiring 1000 having terminal electrodes (not shown) at its ends.

A prepreg substrate 1020 is prepared which comprises an uncured resin sheet 1001a containing a resin as a main component and having a passive element 1006a in the form of a chip which has terminal electrodes on at least its both ends. It is noted that the resin sheet 1001a has a through hole 1090 in a predetermined region, and the through hole is filled with a conductive paste.

Similarly, a prepreg substrate 1030 is prepared in which passive elements 1006b and 1006c each having terminal electrodes on at its both ends are embedded in an uncured resin sheet 1001b containing a resin as a main component.

It is noted that masses of a conductive resin 1008b is preferably printed or potted on the terminal electrodes of the embedded passive elements 1006a and 1006b so as to ensure electrical connection in the final wiring board.

Then, a transfer material 1013 is prepared by forming a wiring pattern 1002a which is connected to the spherical semiconductor element 1003 on a carrier sheet 1011, and printing a conductive adhesive 1008a on a region of the wiring pattern which region is connected to the embedded passive element 1006a similarly to the sixth embodiment. Such transfer material corresponds to the upper side of the spherical semiconductor element 1003 to be embedded.

On the other hand, a wiring pattern 1002b which corresponds to the lower side of the spherical semiconductor element 1003 is prepared not on a transfer material but on a printed wiring board 1010. A bump 1005 and conductive parts (or conductive thin layers) 1008c and 1008d of for example a conductive adhesive may be provided to such wiring pattern 1002b. The printed wiring board 1010 is preferably made of a material of which composition is the same as that of the resin sheet in which the spherical semiconductor element is embedded, but a usual FR-4 substrate, a ceramic substrate or the like may be used.

Then, a resin sheet 1012b is prepared which is to be placed between an upper sheet for embedding 1020 of the spherical semiconductor element 1003 (that is, a prepreg substrate 1020) and a lower sheet 1030 for embedding the spherical semiconductor element 1003 (that is, a prepreg substrate 1030) and which also has a through hole 1009′ at a predetermined position correspondingly to the through hole 1009 and filled with a conductive paste as well as a through hole 1016b at a predetermined position. It is noted that a conductive resin 1008b may be applied to the through hole 1016b.

Further, an uncured resin sheet 1012c is prepared between a lower sheet for embedding 1030 of the spherical semiconductor element and a wiring board 1010, which sheet 1012c has a through holes 1016c and 1016d in predetermined positions which correspond to conductive adhesive applied portions 1008c and 1008d.

Then, the spherical semiconductor element 1003 is located between the uncured resin sheet 1012b and the upper sheet for embedding 1020 while stacking and aligning those sheets as well as the resin sheet 1012c, the resin sheet 1012 c, the wiring board 1010 and the transfer material 1013, followed by bonding with pressing at a high temperature under a high pressure, whereby the sheets for embedding and the resin sheets are made into an electrically insulating substrate in which the spherical semiconductor element 1003 is embedded. By bonding with pressing as described above, the embedded passive elements 1006a and 1006b are connected through the conductive adhesive 1008b while the conductive adhesives 1008a, 1008c and 1008d are connected to the passive elements 1006a, 1006c and 1006d respectively, and further the passive element 1006c is connected to the wiring layer 1002a through the via hole conductors 1009 and 1009′.

Thereafter, the carrier film 1011 is removed so that the wiring pattern 1002a is transferred, whereby the wiring board as shown is in FIG. 4 is obtained.

According to the above mentioned production process, it is possible to electrically connecting transversely using the via hole conductor(s), so that the designing flexibility is greatly improved. Further, the passive elements in the form of the chip can be connected transversely through the conductive adhesive sequentially. Thus, the number of the combinations of the passive elements which can be embedded can be considerably increased.

In any of the above mentioned embodiments, only one spherical semiconductor element is embedded, but a plurality of the spherical semiconductor elements may be embedded. Those skilled in the art can readily conceive and produce the wiring board which has a plural spherical semiconductor elements based on the present disclosure. Therefore, the wiring board as claimed in the claims includes also the embodiments in which a plurality of the spherical semiconductor elements are contained. Also, the formation of the wiring patterns is explained with reference to only using the transfer materials, but it is possible to depositing a metal foil in place of the wiring pattern, and the foil is processed to form a predetermined wiring pattern by for example etching. Further, as used in the seventh embodiment, the wiring pattern may be formed by the wiring board 1010 which has been already produced.

It is noted that in the above mentioned various production processes, the resin sheet, particularly the resin sheets 1012b and 1012c are not essential, but such resin sheet is preferably used since it can prevent the application of an excess form to the other part(s) such as a spherical semiconductor element.

### Eighth Embodiment

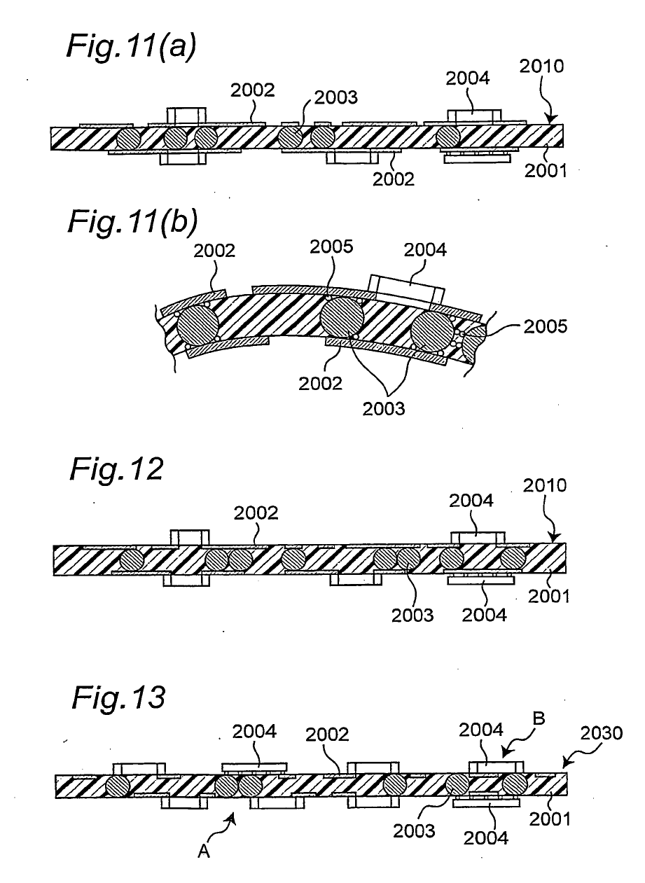

FIG. 11(a) shows a structure of a wiring board having an embedded spherical semiconductor element of the eight embodiment according to the present invention in a cross sectional view, and FIG. 11(b) shows an enlarged portion of such wiring board in its curved form. In the wiring boards of the embodiments according to the present invention which will be described below, the spherical semiconductor element(s) is substantially fully embedded (i.e. in a built-in condition) in the electrically insulating substrate. However, the wiring board having such built-in spherical semiconductor element covers an embodiment in which a very small region of the spherical semiconductor element forms a portion of a main surface of the electrically insulating substrate (that is, such very small region corresponds to a condition that it is almost a point geometrically and such region is substantially flush with the main surface of the electrically insulating substrate).

As shown in FIG. 11, the wiring board 2010 according to the present invention is in a structure which comprises a wiring pattern 2002 made of an electrical conductor such as copper thin film on a surface of an electrically insulating substrate 2001 made of a flexible organic substrate comprising for example a polyimide, and also comprises a spherical semiconductor element 2003 in the inside of the electrically insulating substrate 2001. A wiring (which is not shown for the simplicity and also similarly in FIGS. 12 to 25) formed on a surface of the spherical semiconductor element connects the wiring patterns 2002.

As the spherical semiconductor element 2003, a semiconductor element of a transistor, an IC, an LSI or the like is used. By embedding the spherical semiconductor element 2003 in the electrically insulating substrate 2001, an advanced function and also the high density amounting of the wiring board can be achieved.

It is noted that FIG. 11 shows one application example in which a plurality of electronic parts 2004 are further mounted onto a main surface of the wiring board 2010.

In the present embodiment, it is clear from FIG. 11(a) that a thickness of the electrically insulating substrate 2001 is almost the same as a diameter of the spherical semiconductor element 2003, so that a thickness of the wiring board is relatively small. Therefore, the shown wiring board is flexible as a whole, and a wiring board can be provided wherein electronic parts are densely mounted. As shown in FIG. 11(b), the spherical semiconductor element 2003 can connect to the wiring patterns 2002 on the electrically insulating substrate 2001 by means of the bumps 2005 of the wirings (not shown) which are formed on the main surface of the spherical semiconductor element. Further, the spherical semiconductor elements may be electrically connected to each other in the inside of the electrically insulating substrate 2001.

When the wiring board according to the present invention is curved, there may arise a difference between a stress generated in the upper part of the wiring board and a stress generated in the lower part of the wiring board, which difference can be relaxed because of the spherical form of the spherical semiconductor element. Thus, even though the semiconductor device is embedded in wiring board, such wiring board can be inflected without destroying the semiconductor device, and therefore the flexibility is provided to the wiring board. In the wiring board according to the present invention described above and also below, the wiring patter 2002 is not limited to that made of the copper thin film, and it may be formed by using a metal foil other than copper film or a conductive paste.

Further, in the wiring board according to the present invention described above and also below, the electronic parts 2004 may be mounted onto one or both surfaces of the spherical semiconductor element embedded wiring board as shown in FIG. 11, and such electronic parts may be passive electrodes (such as inductors, capacitors and resistors), semiconductor elements and the like.

### Ninth Embodiment

The ninth embodiment of the present invention will be explained while using the same numerals as in the eighth embodiment for the same members as in the eighth embodiment. It is noted that this is also applicable to the numerals used in the drawings with reference to which the embodiments of the present invention will be explained.

FIG. 12 shows a cross sectional view of a structure of a wiring board 2002 of the second embodiment according to the present invention which is similar to that shown in FIG. 11. What is different in the present embodiment from the eighth embodiment is that the wiring patterns 2002 are embedded in the electrically insulating substrate 2001 such that the exposed surfaces of the wiring patterns 2002 are flushed with the main surfaces of the electrically insulating substrate 2001. Thus, the thickness of the electrically insulating substrate 2001 is almost the same as a sum of the diameter of the spherical semiconductor element 2003 and the thicknesses of the wiring patterns 2002, and the surfaces of the electrically insulating substrate 2020 is almost smooth in a condition wherein no electronic part 2004 is mounted on the electrically insulating substrate.

### Tenth Embodiment

FIG. 13 shows a cross sectional view of a structure of a wiring board 2030 of the tenth embodiment according to the present invention. In the present embodiment, a thickness of the electrically insulating substrate 2001 is almost the same as a diameter of the spherical semiconductor element 2003, which is embedded in the electrically insulating substrate 2001 is not directly connected to the wiring pattern 2002. Thus, the electronic part 2004 mounted on the main surfaces of the wiring board is connected directly to terminal electrodes of the spherical semiconductor element 2003 not through a wiring pattern 2002 as shown with the arrow “A” or connected directly to the spherical semiconductor element 2003 and the wiring pattern 2002 as shown with the arrow “B.” Thus, since the wiring of the spherical semiconductor element does not directly connect to the wiring pattern, a thickness of the wiring board 2030 in the present embodiment is smaller than that of the wiring board in the eighth or ninth embodiment by the thickness of the wiring board. As seen from FIG. 13, an exposed surface (which is in fact a point) of the spherical semiconductor element and an exposed surface of the wiring pattern are at the same level as a surface of the wiring board.

### Eleventh Embodiment

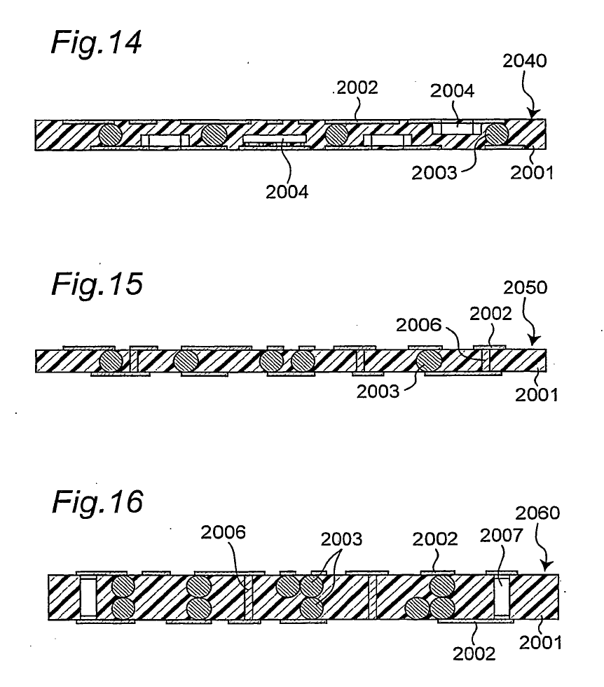

FIG. 14 shows a cross sectional view of a structure of a wiring board 2040 of the eleventh embodiment according to the present invention. In the present embodiment, similarly to the ninth embodiment, the spherical semiconductor element 2003 connects the wiring patterns 2002 which are formed such that they are flush with the main surfaces of the electrically insulating substrate 2001 as shown. The electronic parts 2004 which are embedded in the above mentioned eighth to tenth embodiments are embedded in the electrically insulating substrate 2001, which leads to a further higher amounting density.

### Twelfth Embodiment

The twelfth embodiment is explained with reference to FIG. 15, which shows a cross sectional view of a wiring board 2050 of the present embodiment. A basic structure of the present embodiment is the same as that of the eighth embodiment shown in FIG. 11 (provided that the electronic parts are omitted in FIG. 15), but in the present embodiment, via hole conductors 2006 in addition to the spherical semiconductor elements 2003 are already formed in the electrically insulating substrate 2001 so as to electrically connect the wiring patterns 2002 on the both sides of the electrically insulating substrate 2001. Thus, the present embodiment further improves the flexibility upon the circuit designing. It is noted that the via hole conductors 2006 are preferably formed of for example a thermosetting resin and a conductive filler or formed in a plating manner.

### Thirteenth Embodiment

FIG. 16 shows a structure of a wiring board 2060 of the present embodiment, in which two spherical semiconductor elements 2003 are located while connected along a thickness direction and/or a plane spreading of the electrically insulating substrate 2001 as clearly seen from FIG. 16. Not shown in FIG. 16, the spherical semiconductor elements 2003 are connected through terminal electrodes and/or bumps 2005 formed on the spherical surfaces which are in contact with each other as shown in FIG. 11(b).

An feature of the present embodiment in addition to stacked and embedded spherical semiconductor elements 2003 is that a via hole conductor 2006 is provided as in the twelfth embodiment, and further that an electronic part 2007 such as a resister, a capacitor or the like is embedded in the wiring board as shown which so that it connects the wiring patterns 2002 on the main surfaces on the both sides of the wiring board.

It is noted in this embodiment that the number of the spherical semiconductor element to be connected is not limited to two as shown, and three or more spherical semiconductor elements may be connected along a thickness direction and/or a plane spreading direction of the wiring board.

The wiring board 2060 according to the present embodiment allows the higher density amounting while the number of the electronic parts mounted on a surface of the wiring board can be reduced.

### Fourteenth Embodiment

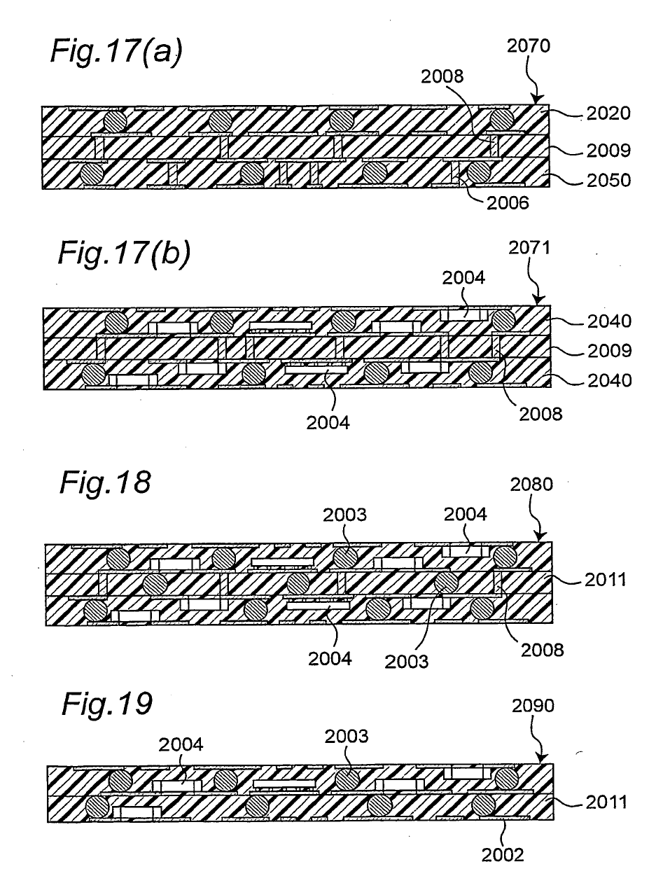

The fourteenth embodiment is explained with reference to FIGS. 17(a) and 17(b). FIG. 17(a) shows a structure of a wiring board 2070 of the fourteenth embodiment. As shown in the drawing, the wiring board comprises a multilayer wiring structure in which an inner wiring pattern(s) are provided.

The present embodiment corresponds to a three layer structure which is formed by superimposing the wiring board 2020 of the ninth embodiment (provided that comprising no electronic part) and the wiring board 2050 of the twelfth embodiment in which the wiring patterns 2002 are flushed with the surfaces of the electrically insulating substrate 2001 and the via hole conductors 2006 are formed through a interconnecting wiring board 2009 which is made of a flexible epoxy resin or the like and which has the via hole conductors 2008. It is noted that the via hole conductors 2008 are preferably formed of for example a thermosetting resin and a conductive filler or formed in a plating manner.

Also, as shown in FIG. 17(b), two of the wiring boards 2040 which are obtained in the eleventh embodiment may be superimposed through an interconnecting wiring board 2009 similar to the above, so that a multilayer wiring board 2071 with embedded electronic parts can be obtained.

### Fifteenth Embodiment

FIG. 18 shows a wiring board 2080 of the present embodiment. What is different in the present embodiment from the fourteenth embodiment is that the interconnecting wiring board 2011 has an embedded spherical semiconductor element(s) 2003 in addition to the via hole conductors 2008.

It is noted that in FIGS. 17 and 18 corresponding to the fourteenth and fifteenth embodiments respectively, the electronic parts 2004 are embedded, but they may be not embedded in but mounted on surfaces of the electrically insulating substrates 2001.

Further, the wiring boards explained in the fourteenth and fifteenth embodiments are in the three-layer structure, but it is possible to form a structure which is in a four- or more-layer structure.

### Sixteenth Embodiment

A multilayer wiring board according to the present invention is not limited to those of the fourteenth and fifteenth embodiments produced by superimposing through the interconnecting wiring board, but it can be produced by a transfer manner, a build-up manner or the like in which the formation of the wiring pattern 2002 on the electrically insulating substrate 2001 is sequentially carried out in the production step as shown in FIG. 19. That is, the wiring board 2090 of the sixteenth embodiment becomes a wiring board which is thin and of a multilayer structure as shown in FIG. 19.

It is noted that the drawing shows a cross sectional view in which the electronic parts 2004 are embedded, but that the electronic parts may be mounted on the surfaces of the wiring board and/or via hole conductors may be provided inside the electrically insulating substrate 2001. Further, selection of the formation of the wiring patterns 2002 on the surface of the electrically insulating substrate 2001 and/or the formation of the wiring patterns 2002 which are flush with the surfaces of the electrically insulating substrate 2001 may be optionally carried out.

In addition, FIG. 19 shows a structure which comprises two electrically insulating substrates 2001, but it is possible to form a multilayer structure which comprises three or more electrically insulating substrates.

It is noted that as a material which forms the electrically insulating substrate of the wiring board according to the present invention described above and below, the polyimide resin and the epoxy resin are preferable, and also a resin composition is preferable of which main component is at least one flexible material selected from a phenol resin, a wholly aromatic polyamide resin, a wholly aromatic polyester resin, an aniline resin, a polydiphenyl ether resin, a polyurethane resin, a urea resin, a melamine resin, a xylene resin, a diallyl phthalate resin, a phthalic resin, an aniline resin, a fluororesin, and a liquid crystal polymer, and any combination thereof.

It is noted that in order to make substantially a whole of the wiring board flexible, a curable resin which exhibits the flexibility after being cured is used as a main component for the electrically insulating substrate. As such resin, one resin which provides an intended flexibility is selected from a polyimide resin, a wholly aromatic polyamide resin, an epoxy resin, a phenol resin, a wholly aromatic polyester resin, an aniline resin, a polydiphenyl ether resin, a polyurethane resin, a urea resin, a melamine resin, a xylene resin, a diallyl phthalate resin, a phthalic resin, a fluororesin, a liquid crystal polymer, PET (polyethylene terephthalate), PEN (polyethylene naphthalate) and the like. Depending on the properties of the spherical semiconductor element to be used, appropriately blending such resin as a main component which forms the electrically insulating substrate can provide an improved high frequency property and also different flexibility. It is noted that the epoxy resin is preferable from viewpoints of its heat resistance and adhesive property, and that the polyimide resin may be used so as to provide with more sufficient flexibility.

In other embodiment, an elastomer is used in place of or in addition to using the curable resin which shows the flexibility after being cured. In the latter embodiment, the elastomer is added to such curable resin, and the curable resin itself does not have to be so flexible after being cured. As such elastomer, a block copolymer of styrene and butadiene, a polymer produced by hydrogenating a double bond of such copolymer, and a hydrogenated styrene based thermoplastic elastomer are exemplified. The addition of the elastomer leads not only to the provision of the flexibility but also to the improvement in its weather resistance, heat resistance, chemical resistance against for example acids and alkalis.

By selecting an amount of the elastomer to be added, the electrically insulating substrate and thus the wiring board can have a desired elastic modulus. Generally, an amount of the elastomer to be added is preferably in the range between 5% by weight and 30% by weight to an amount of the resin(s) which forms the electrically insulating substrate expect the elastomer. When necessary, an inorganic filler of alumina, silica, aluminum nitride, boron nitride, magnesium oxide or the like is added to such organic polymer substrate, which provides the flexibility while improving a surface rigidity of the wiring board.

Particularly, using an inorganic filler made of alumina, boron nitride or the like is preferable since it improves the heat radiation property of the wiring board. In the present invention, the technique disclosed in Japanese Patent Kokai Publication No. 1999-220262 can be employed for the substrate in which such inorganic filler is used.

It is often that the inorganic filler which is mixed into the resin, particularly the thermosetting resin is generally used in the form of fine particles, and because of adsorption of their large surface areas, a viscosity of a composite of the resin and the inorganic filler is increased so that an amount of the inorganic filler is limited, which may adversely affects the sufficient heat radiation property, a handling property of the composite and the like.

Such inorganic filler which is used for the electrically insulating substrate of the present invention is preferably surface-treated with a saturated or unsaturated fatty acid such as stearic acid, oleic acid or linoleic acid or the like so as to form a coating layer around the particles, which reduces the surface areas of the fine particles so that their affinity as to the resin such as a thermosetting resin is desirably increased. By promoting the adhesion property of the inorganic filler as to the resin such as a thermosetting resin, the flexibility and a toughness of the wiring board according to the present invention can be further improved.

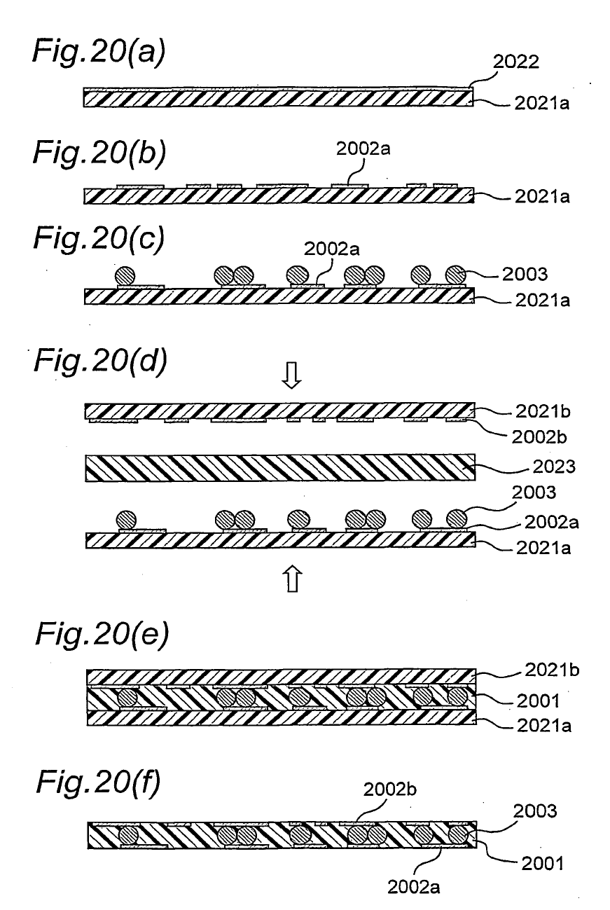

FIGS. 20(a) to 20(f) show one example of other process of producing a wiring board according to the present invention.

First, a copper foil 2022 is formed on a carrier (or support substrate) 2021a comprising a stainless steel sheet of which surface is coated with a release agent as shown in FIG. 20(a), and then a first wiring pattern 2002a is formed as shown in FIG. 20(b) by a photolithographic manner and an etching manner. Thereafter, a spherical semiconductor element 2003 having a wiring on its surface is bonded to a predetermined position of the first wiring pattern 2002a by heating a gold bump or a solder bump formed on a terminal of the first wiring pattern 2002a and/or the spherical semiconductor element 2003.

It is noted that as the supporting substrate, a release film may be used which is made of an electrically insulating material. Further, when a surface of the wiring pattern 2002 is plated, a corrosion resistance, an electric conducting property and the like can be improved.

For the purpose of the electric connection between the terminal of the first wiring pattern 2002a and the terminal of the wiring of the spherical semiconductor element 2003, a conductive adhesive of which conductive component is made of gold, silver, copper, silver-palladium alloy or the like may be used. Further, using a sealing resin, the spherical semiconductor element 2003, the spherical semiconductor element 2003 and the bump(s) 2005 or at least a portion of the connection of the electrically insulating substrate 2001 may be sealed.

Then, as shown in FIG. 20(d), the support substrate 2021a on which the first wiring pattern 2002a is located at a predetermined position is aligned, through a prepreg 2023 of a thermosetting resin of which main component is a polyimide resin containing an inorganic filler of aluminum nitride powder, with other support substrate 2021b on which the second wiring pattern 2002b is formed, through a release material, at a predetermined position in other step, followed by pressing with a pressure of about 30 kg/cm² as indicated with the arrows while heating at 200° C. which is a curing temperature of the thermosetting resin, so that as shown in FIG. 20(e), the spherical semiconductor elements 2003 are pressed and embedded into the prepreg substrate 2023 while the second wiring pattern 2002b is connected as predetermined, and the prepreg substrate 2023 is fully cured to be an electrically insulating substrate 2001. It is noted that depending on the polymer to be used, the heating temperature and the pressing pressure are desirably selected in the ranges for example between 150° C. and 260° C. and between 5 kg/cm² and 150 kg/cm² respectively.

Then, the support substrates 2021a and 2021b are removed, so that the wiring board as shown in FIG. 20(f) is obtained.

Thus, the present invention provides a process of producing a wiring board which contains a spherical semiconductor element, comprising the steps of:

(5-1) providing a transfer material by forming a predetermined first wiring pattern on a carrier sheet;

(5-2) mounting, on a predetermined position of the first wiring pattern of the transfer material, at least one spherical semiconductor element having a wiring on its surface so as to provide a first transfer material;

(5-3) providing a second transfer material by forming a predetermined second wiring pattern on a carrier sheet;

(5-4) superimposing a prepreg substrate made of a uncured resin composition and the two transfer materials such that the first wiring pattern and the second wiring patter are opposed through the prepreg substrate, followed by pressure bonding them at a heated temperature under an elevated pressure, so that the spherical semiconductor element is embedded into an electrically insulating substrate while the first wiring pattern and the second wiring pattern are connected by the wiring of the spherical semiconductor element; and

(5-5) removing the carrier sheets so as to transfer the first wiring pattern and the second wiring pattern.

Then, other process of producing a wiring board according to the present invention will be explained.

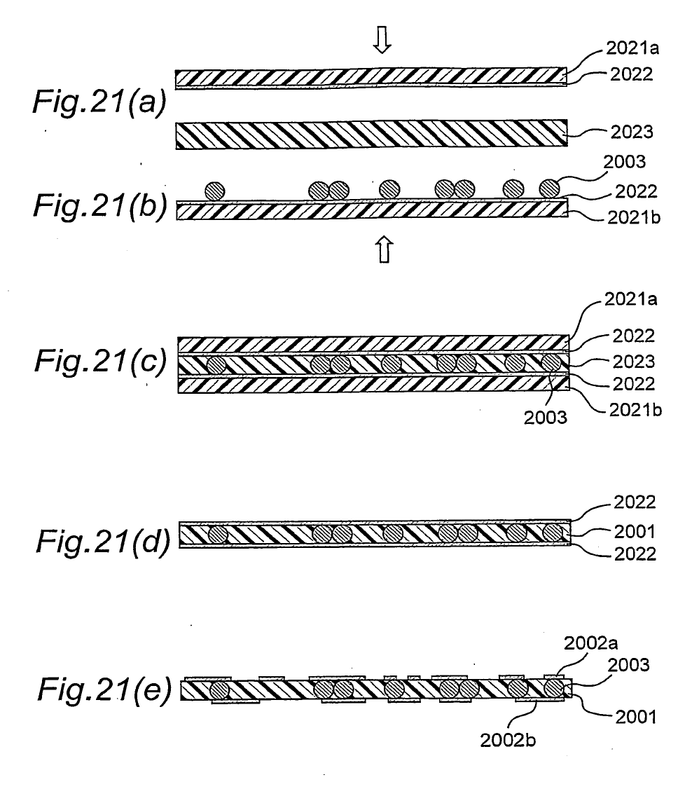

What is different in this process from the process which is explained with reference to FIG. 20 is that a side of a copper foil 2022 which is formed on a support substrate 2021a through a release agent faces a side of a spherical semiconductor element which is mounted onto a copper foil 2022 at a predetermined position formed on other support substrate 2021b, and that between those sides, a prepreg substrate 2023 is located which is made of a thermosetting resin of which main component is an epoxy resin containing an inorganic filler of boron nitride powder, followed by pressing with a pressure of about 70 kg/cm² as indicated with the arrows while heating at a temperature of 250° C., so that as shown in FIG. 21(c), the spherical semiconductor elements 2003 are embedded into the prepreg substrate 2023 while the prepreg substrate 2023 is fully cured to be an electrically insulating substrate 2001.

Then, the support substrates 2021a and 2021b are removed, and the copper foils bonded to the both surface of the electrically insulating substrate 2001 is treated in a photolithographic manner and an etching manner so as to form wiring patterns 2002a and 2002b as shown in FIG. 21(e), and the wiring board is obtained in which those wiring patterns according to the present invention are connected by the wirings of the spherical semiconductor elements.

Thus, the present invention provides a process of producing a wiring board which contains a spherical semiconductor element, comprising the steps of:

(6-1) providing a first carrier sheet comprising a first metal layer on its surface;

(6-2) mounting, on a second metal layer placed on a surface of a second carrier sheet, at least one spherical semiconductor element having a wiring on its surface;

(6-3) superimposing while aligning the first carrier sheet and the second carrier sheet such that their metal layers are opposed to each other through a prepreg substrate made of an uncured resin composition, followed by pressure bonding them at a heated temperature under an elevated pressure, so that a laminate is obtained in which the spherical semiconductor element is embedded into an electrically insulating substrate while the first metal layer and the second metal layer are connected to the spherical semiconductor element; and

(6-4) removing the first carrier sheet and the second carrier sheet from the laminate, followed by processing as predetermined to obtain a first wiring pattern a the second wiring pattern.

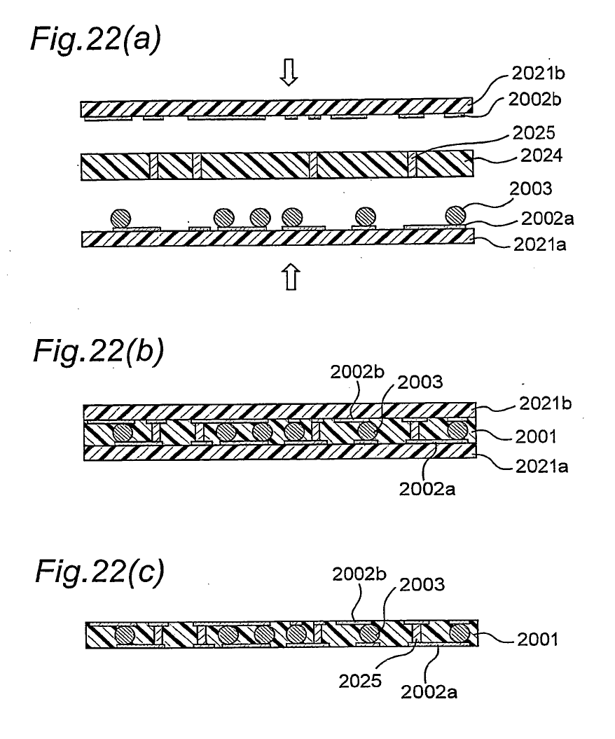

FIGS. 22(a) to 22(c) shows late steps of other example of a process of producing a wiring board according to the present invention, and the steps prior to the late steps as well as the materials to be used are the same as those which are described with reference to FIG. 20.

What is different in this embodiment from the process which is explained with reference to FIG. 20 is that in place of the prepreg substrate 2023, a prepreg substrate 2024 including via holes 2025 at predetermined positions which are filled with a conductive paste. Such prepreg is obtained by forming holes through a prepreg substrate using a carbon dioxide laser or excimer laser processing, a punching processing or the like followed by printing, into the holes, a conductive paste comprising a thermosetting resin and conductive powder mixed therein of for example gold, silver, copper, nickel or the like.

The prepreg which is prepared thus 2024 is located between and aligned with carriers 2021a and 2021b, followed by heating with pressing as indicated with the arrows under the same conditions as those in the process which is described above with reference to FIG. 20, so that the prepreg substrate 2024 is fully cured while also the conductive paste is fully cured to form the via hold conductors 2025.

Thereafter, by removing the support substrates 2021a and 2021b, a wiring board is obtained in which the wiring patterns 2002a and 2002b are connected by the via hole conductors 2025 and wiring of the spherical semiconductor element 2003.

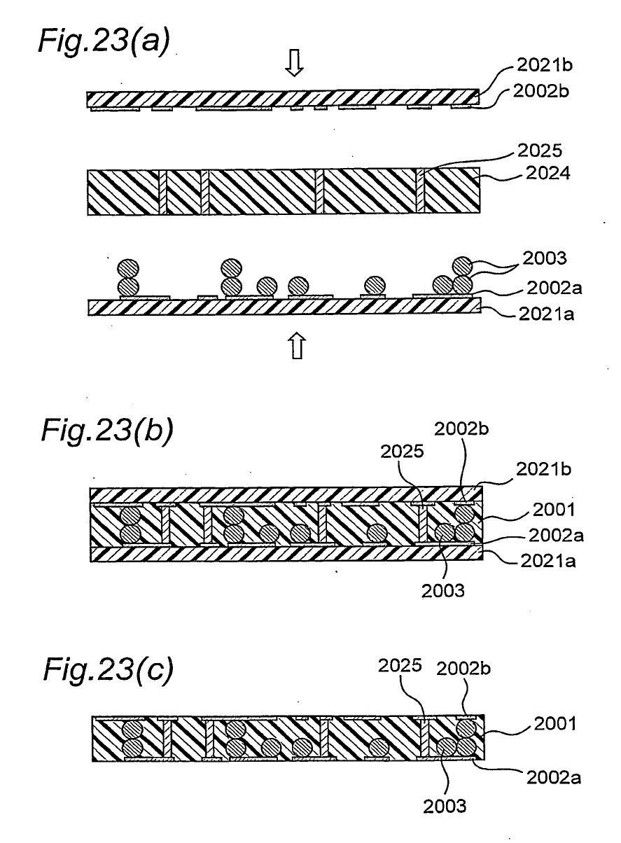

FIGS. 23(a) to 23(c) shows late steps of one example of a process of producing a wiring board according to the present invention, which process resembles the production process described with reference to FIG. 22. What is different in this process from the process which is explained with reference to FIG. 22 is that two of spherical semiconductor elements are doubly and vertically mounted at a predetermined position on a wiring pattern 2002a which is formed on an upper surface of a support substrate 2021a. Therefore, a thickness of the prepreg substrate 2024 and a length of the via hole conductor 2025 are made a thickness and a length which correspond to two of the spherical semiconductor element. Thus, by superimposing and pressing them along the arrow directions as shown, the doubly mounted spherical semiconductor elements are embedded in the prepreg substrate 2024, so that an upper terminal of the upper spherical semiconductor element 2003 is connected to a terminal of the wiring pattern 2002b and a lower terminal of the lower spherical semiconductor element 2003 is connected to a terminal of the wiring pattern 2002a as shown in FIG. 23(b). In this case, the wirings of the spherical semiconductor elements are connected to the wiring patterns, and the both of the spherical semiconductor elements are directly connected. That is, the wiring patterns are connected by the wirings of the spherical semiconductor elements.

Then, removing the support substrates 2021a and 2021b, the wiring board according to the present invention as shown in FIG. 23(c) is obtained in which the spherical semiconductor elements are doubly connected.

It is noted that FIG. 23 shows the embodiment in which two of the spherical semiconductor elements are doubly and vertically stacked, but it is also possible that three or more spherical semiconductor elements may be optionally stacked vertically depending on a design of an electronic device in which the wiring board is contained.

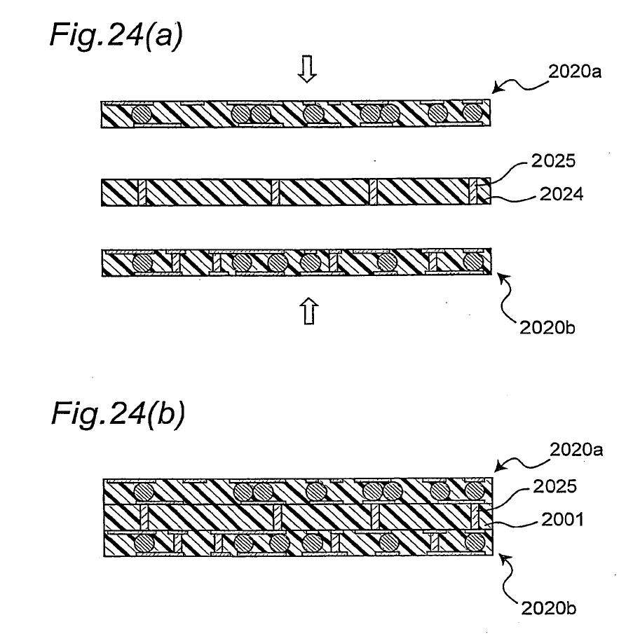

Next, a process of producing a wiring board in the form of a multilayer wiring structure. FIG. 24 shows late steps of such process. First, two kinds of the wiring boards 2020a and 2020b according to the present invention are prepared, and they are located and aligned as shown in FIG. 24(a) such that those wiring boards are opposed to each other through a prepreg substrate 2024 in which via hole conductors 2025 are formed, followed by heating and pressing along directions as shown with the arrows.

According to such process, a multilayer wiring board having wiring patterns as four wiring layers as shown in FIG. 24(b) can be produced. In the wiring board, the upper spherical semiconductor element and the lower spherical semiconductor element are connected to the upper wiring pattern and to the lower wiring pattern respectively, and those spherical semiconductor elements are connected by the inner wiring pattern and the via hole conductors 2025. That is, the wirings of the two spherical semiconductor elements are connected to the upper wiring pattern and the lower wiring pattern through the via hole conductors.

It is noted that FIG. 24 explains the example in which two spherical semiconductor element embedded wiring boards are aligned while one prepreg substrate is located between them, followed by laminating them together, but other prepreg substrate(s) and the wiring boards according to the present invention may be located alternately, so that the wiring board according to the present invention can be a wiring board which comprises more wiring patterns as the wiring layers.

Further, FIG. 24 shows the example in which the prepreg substrate 2024 includes only the via hole conductors 2025 in the inside thereof, but the prepreg substrate 2024 may have an embedded(s) spherical semiconductor element at a predetermined position.

### Seventeenth Embodiment

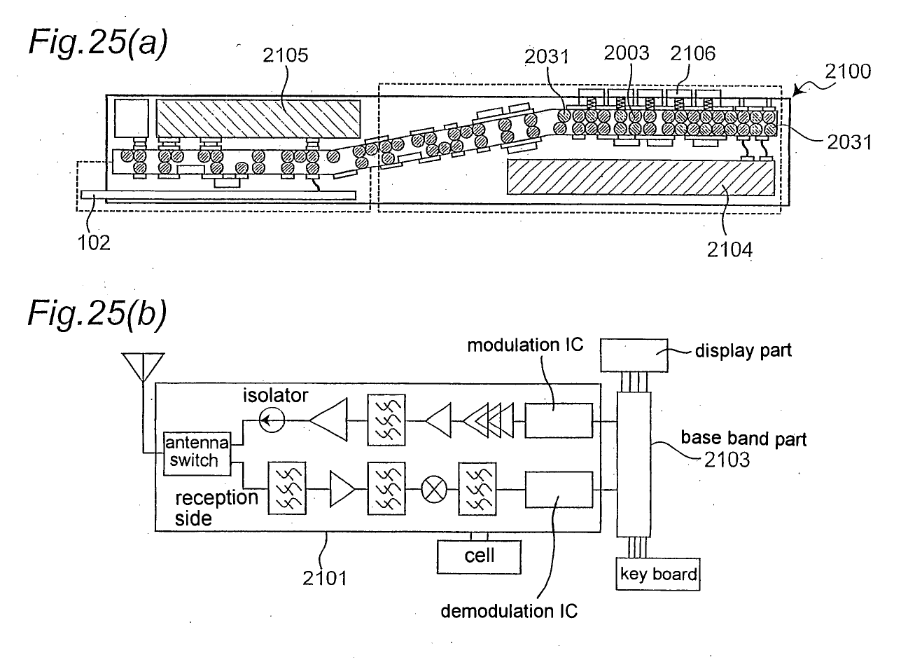

With reference to FIG. 25, a mobile phone is explained which is one example of an electronic device which includes the wiring board according to the present invention.

FIG. 25(a) shows a schematic cross sectional view of a mobile phone 2100 of a single housing type in which the wiring board according to the present invention is located. FIG. 25(b) is a circuit block diagram of the mobile phone. A high frequency circuit part 2101 is placed above an antenna 2102 shown in FIG. 25(a), and a base band part 2103 is placed in a region which is present above a cell 2104. The high frequency circuit part 2101 is made of an antenna switch, an isolator, an amplifying part, a filter, a modulation IC, a demodulation IC and the like. The antenna switch and the antenna are electrically connected, and the modulation IC and the demodulation IC are electrically connected to the base band part 2103. Further, the base band part 2103 is electrically connected to a display part and a key board.

As shown in FIG. 25(a), the display part 2105 is placed in one end of the single housing type mobile phone 2100, and an input operation part 2106 is placed in the other end, and therefore, the wiring board is required to have a flexibility which allows it to be contained in its bent situation as shown. On the other hand, a region of the wiring board which is located below the input operation part 2106 is required to be rigid (or stiff) so that it can endure a pressing force through the input operation part.

With the wiring board according to the present invention, in addition to the spherical semiconductor elements, insulating spherical elements (that is, insulation material in the form of spheres, such as silica balls) 2031 which do not substantially affect their adjacent circuit(s) circumstances ambient are also located as rigidizing elements in a region of the wiring board which region is just below the input operation part, so that such region is relatively rigid to the other regions. That is, the wiring board according to the present invention 2100 has various flexibilities depending on its regions. It is noted that in place of the above mentioned insulating spherical elements, an inorganic filler such as alumina powder, a silica powder or the like may be used. Particularly, it is desirable to use an inorganic filler having a good thermal conductivity such as alumina, aluminum nitride or the like in the wiring board in which an exothermic LSI is contained. Further, by embedding an electronic part may be embedded in the wiring board as a rigidizing element while electrically connected to the wiring patterns, the rigidity of the wiring board can be improved.

A conventional wiring board in which a thermosetting resin and a fabric such as a non-woven fabric are used as main components is in fact rigid, and also there is an idea that having a flexibility is not preferable, so that bending the wiring board has been difficult. As a result, there is a limitation as the reduction of the size of the mobile phone, particularly its thickness. As clearly seen from the above mentioned seventeenth embodiment, since the spherical semiconductor element embedded wiring board 2100 according to the present invention has various flexibilities depending on its regions, it can be contained in a considerably narrow space of a thinned housing of the mobile phone when it is bent as required. Further, embedding the spherical semiconductor element which functions as an IC omits an IC part which is mounted on a surface of the wiring board, so that the size, particular the thickness of the wiring board can be reduced. It is noted that since the spherical semiconductor element can relax a difference of stresses which act on the spherical semiconductor element because of its shape, a possibility of failure occurrence in the wiring board having the embedded spherical semiconductor element is smaller than that in the wiring board having the plate type semiconductor element when such wiring boards are bent.

### Eighteenth Embodiment

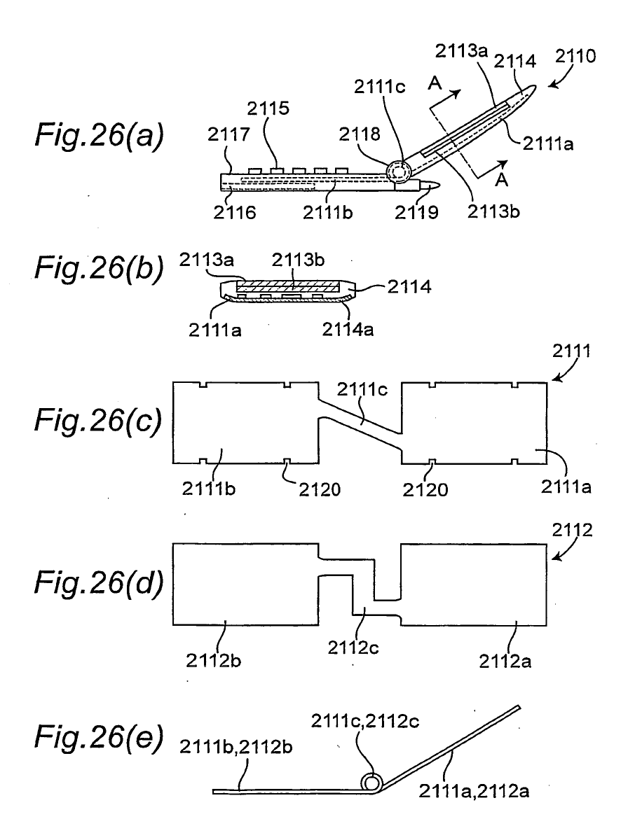

With reference to FIG. 26, a mobile phone of a folding type having two housings is explained which is other example of an electronic device which includes the wiring board according to the present invention.

FIG. 26 shows one example of a folding type mobile phone 2110 which contains a spherical semiconductor element embedded wiring board which is the wiring board according to the present invention. FIG. 26(a) shows a conceptional side view of the folding type mobile phone, FIG. 26(b) is a cross sectional view along a line A-A in FIG. 26(a), FIGS. 26(c) and 26(d) shows schematic plan views of two kinds of the spherical semiconductor element embedded wiring board according to the present invention which can be used for the folding type mobile phone, and FIG. 26(e) shows a side view of the spherical semiconductor element embedded wiring board according to the present invention which is in its bent form (which corresponds to the situation shown with a broken line in FIG. 26(a)) so as to be housed in the folding type mobile phone.

It is noted that each of cross sectional structures of the wiring boards 2111 and 2112 shown in FIGS. 26(c) and 26(d) is the same as that of any one of the above mentioned eighth to sixteenth embodiments, and in those drawings, the wiring patterns and the surface mounted electronic parts are omitted and only overall shapes of the wiring boards are shown.

As shown in FIG. 26(a), the folding type mobile phone 2110 has a configuration in which a displaying housing 2114 which houses a display part 2113a comprising a liquid crystal element, an EL element or the like and its driving module 2113b and an input side housing 2117 which houses an input operation part 2115 such as a key board and a cell 2116 are linked such that they can be into a folded form around a hinge part 2118. It is noted that an antenna 2119 is located in the input side housing 2117, and it may be located in an upper part of the displaying housing 2114.

The shown folding type mobile phone comprises a wiring board 2111 which is made of a single substrate, and the wiring board is constructed such that an upper part thereof 2111a has a moderate flexibility and a connecting part 2111c has a much higher flexibility by appropriately providing the rigidizing elements depending on regions of the wiring board.

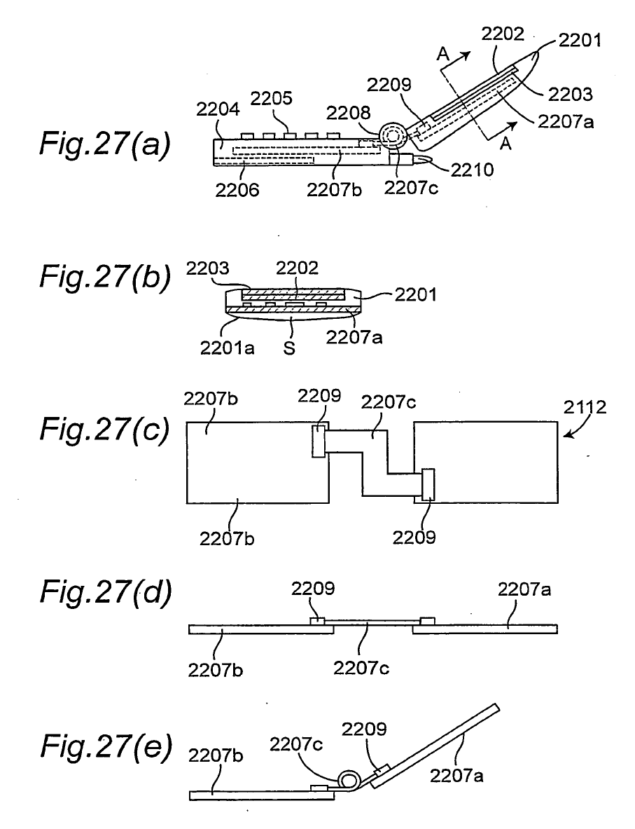

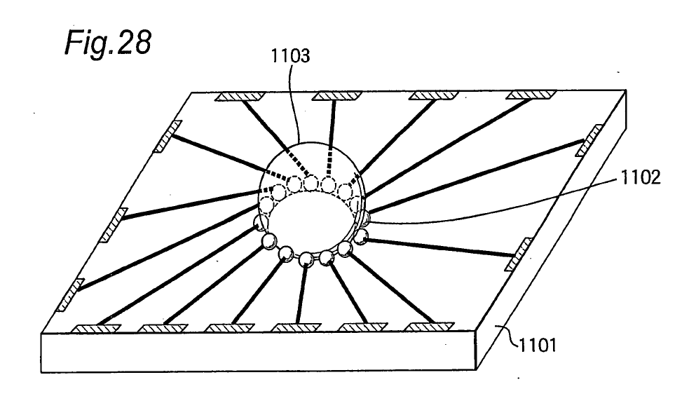

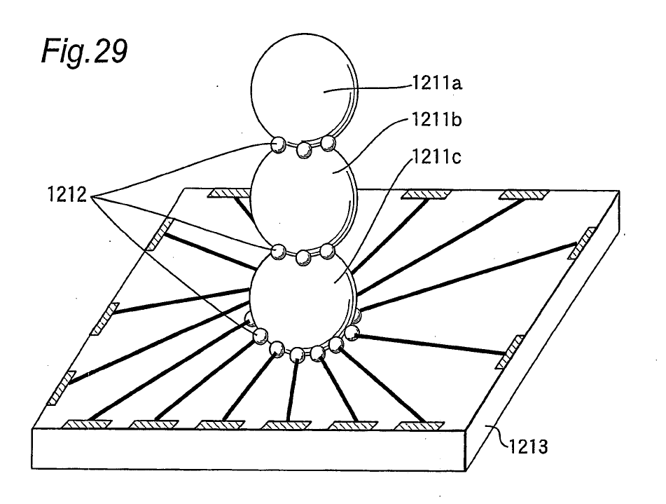

Such moderate flexibility of the upper part 2111a of the wiring board allows the upper part 2111a to follow a curved surface of a backside part 2114a of the displaying housing 2114 while the upper part 2111a is located below the display part 2113a and the driving module 2113b as shown in FIGS. 26(a) and 26(b), so that no wasted space is formed. That is, it is clear when FIGS. 26(a) and 26(b) are compared with FIGS. 27(a) and 27(b) that the space indicted with “S” in FIG. 27(b) is deleted, so that the wiring board according to the present invention contributes to thinning the thickness of the displaying housing 2114.

The wiring board 2111 of the present embodiment which is used for the mobile phone comprises the upper part 2111a and a lower part 2111b which are integrated by the connecting part 2111c as shown in FIG. 26(c). As seen from FIG. 26(c), these three parts are not made by connecting separate wiring boards, but made of an originally single substrate, so that no conventional connection such as that formed by soldering or a connector is required.

With the above mentioned wiring board, a thickness of the connector can be omitted, and thus when the connecting part 2111c is merely rolled up as shown in FIG. 26(e), the wiring board can be contained within the housings in the shape as shown with a broken line in FIG. 26(a), which leads to the reduction of the thickness of the input side housing 2117.

It is noted that when a notch 2120 is formed in the wiring board 2111 as shown in FIG. 26(c), a reinforcing rib which is formed on a mobile phone housing so as to confer the rigidity can be fitted into and fixed by the notch. Thus, the wiring board can be so large as effectively utilize the whole area of the wiring board substantially while it is contained in the housing without a jounce, whereby other connecting member such as a fixing screw can be omitted.

FIG. 26(d) shows other wiring board 2112 according to the present invention of which upper part 2112a and lower part 2112b are connected with a connecting part 2112c in a crank form. It is noted that a planar shape of the wiring board according to the present invention is not particularly limited to those as shown in FIGS. 26(c) and 26(d), and it may be any shape as far as it can be the form as shown in FIG. 26(e) when the wiring board is bent. Further, the wiring board shown in FIG. 26(e) may have the notches 2120 as shown in FIG. 26(c).

The wiring board 2111 or 2112 according to the present invention is formed in a single step such that it comprises the upper part 2111a or 2112a which is to be contained in the displaying housing and the lower part 2111b or 2112b which is to be contained in the input side housing are linked by the connecting part 2111c or 2112c which functions as a wiring cable, and those parts are formed simultaneously as shown in FIG. 26(c) or 26(d), so that no other connecting means such as a connector is required.

As described above, the parts 2111a and 2111b (or 2112a and 2112b) and the wiring cable 2111c (or 2112c) of the wiring board have the different flexibilities respectively. That is, the wiring cable 2111c (or 2112c) is the most flexible so that it can be housed within the hinge part 2118 in its rolled up form, the upper part 2111a (or 2112a) has the moderate flexibility so that it can be located accurately in the displaying housing while it closely contact the inner surface of the backside of the housing, and the lower part 2111b (or 2112b) has a rigidity which is sufficient to withstand a key board pressure.

FIG. 26(d) shows the wiring cable 2112c of which shape is different from that shown in FIG. 26(c), and a preferable shape of the wiring cable is selected depending on the form of the hinge part 2118. It is noted that corners in regions of the wiring cable 2111c or 2112c which regions of the wiring cable lead to the wiring board parts 2111a and 2111b or 2112a and 2112b respectively are desirable in smooth arc shapes (i.e. to be round by chamfering), which is effective to improve the reliability of the wiring board.

### INDUSTRIAL APPLICABILITY

In the wiring board according to the present invention, at least one, preferable a plurality of the spherical element, for example the spherical semiconductor element are embedded in the electrically insulating substrate made of the thermosetting resin which is preferably flexible, and such elements connect the wiring patterns, whereby the electronic circuit(s) are formed within the wiring board, which is useful as the high density wiring board. Thus, such wiring board can be used as the multilayer wiring board which is contained in the thinned and compact portable electronic device such as a mobile phone, a video camera, a digital camera or the like.

1. A wiring board which comprises at least one spherical semiconductor element, an electrically insulating substrate and a predetermined wiring pattern which is located on each main surface of the electrically insulating substrate,
wherein the electrically insulating substrate is made of a resin composition, and the wiring pattern formed on one main surface of the electrically insulating substrate and the wiring pattern formed on an opposite main surface are electrically connected through a wiring formed on a surface of the spherical semiconductor element, and the spherical semiconductor element is embedded at least partially in the electrically insulating substrate.

2. The wiring board according to claim 1 wherein the wiring patterns on the both main surfaces of the electrically insulating substrate are also connected by means of a via hole conductor which is provided in the electrically insulating substrate.

3. The wiring board according to claim 1 wherein a passive element and/or an electronic part is further embedded in the electrically insulating substrate.

4. The wiring board according to claim 3 wherein at least one of the wiring pattern formed on one main surface of the electrically insulating substrate and the wiring pattern formed on an opposite main surface is connected to the passive element and/or the electronic part through the via hole conductor.

5. The wiring board according to claim 1 wherein a portion of the spherical semiconductor element is exposed from the electrically insulating substrate and a bump is formed on a periphery of the exposed spherical semiconductor element above the electrically insulating substrate, the wiring patterns formed on the main surfaces of the electrically insulating substrate and the wiring of the spherical semiconductor element are connected through the bump.

6. The wiring board according to claim 1 wherein the electrically insulating substrate is a transparent substrate.

7. The wiring board according to claim 1 wherein the electrically insulating substrate is made of a mixture which contains an inorganic filler and a thermoset resin.

8. The wiring board according to claim 1 wherein it comprises other spherical element which is made of an electrically insulating material in addition to the spherical semiconductor element.

9. The wiring board according to claim 1 wherein a plurality of the spherical semiconductor elements are embedded such that they are arranged along a thickness direction of the wiring board.

10. The wiring board according to claim 1 wherein the electrically insulating substrate further comprises at least one layer of a wiring pattern in its inside, whereby the wiring board is a multilayer wiring board.

11. The wiring board according to claim 1 wherein at least a portion of the wiring board is flexible.

12. The wiring board according to claim 1 wherein the wiring board is composed of a plurality of wiring board parts which have different flexibilities respectively.

13. The wiring board according to claim 12 wherein the different flexibilities are provided by a rigidizing element(s) which is present in the electrically insulating substrate.

14. The wiring board according to claim 1 wherein at least one of the wiring patterns on the main surfaces of the electrically insulating substrate comprises a terminal of an electronic part which is located on the main surface of the electrically insulating substrate.

15. The wiring board according to claim 1 wherein the electrically insulating substrate of the wiring board is made of a resin composition which contains as its main component at least one elected from the group consisting of a polyimide resin, a wholly aromatic polyamide resin, an epoxy resin, a phenol resin, a wholly aromatic polyester resin, an aniline resin, a polydiphenyl ether resin, a polyurethane resin, a urea resin, a melamine resin, a xylene resin, a diallyl phthalate resin, a phthalic resin, a fluororesin, and a liquid crystal polymer.

16. The wiring board according to claim 15 wherein the resin composition contains at least one inorganic filler selected from the group consisting of alumina, silica, aluminum nitride, boron nitride, and magnesium oxide.

17. The wiring board according to claim 16 wherein the inorganic filler has coatings on its particle surfaces which coatings made of a saturated or unsaturated fatty acid.

18. The wiring board according to claim 1 wherein it has a notch in its periphery.

19. An electronic device which comprises the wiring board according to claim 1.

20. A process of producing a wiring board which contains a spherical semiconductor element, comprising at least the steps of:
(1-a) embedding the spherical semiconductor element totally in a prepreg substrate which is made of a curable resin composition in its uncured condition;
(1-b) forming respectively, on carrier sheets, bumps and wiring patterns which are to be connected through a wiring of the spherical semiconductor element so as to obtain an upper wiring pattern transfer material and a lower wiring pattern transfer material;
(1-c) locating and aligning each of the above mentioned wiring pattern transfer material, through a resin sheet in its uncured condition, on each side of the prepreg substrate in which the spherical semiconductor element is embedded, followed by heating with pressing so as to integrally bond them, whereby the prepreg substrate and the uncured resin sheets are made into an electrically insulating substrate while the wiring patterns are connected with the wiring of the spherical semiconductor element; and
(1-d) removing the carrier sheets and leaving the wiring patterns and the bumps on the electrically insulating substrate so as to transfer them.

21. A process of producing a wiring board which contains a spherical semiconductor element, comprising at least the steps of:
(2-a) embedding a portion of the spherical semiconductor element in a prepreg substrate which is made of a curable resin composition in its uncured condition, so that a portion of the spherical semiconductor element is exposed above at least one main surface of the prepreg substrate;
(2-b) forming respectively, on carrier sheets, bumps and wiring patterns which are to be connected through a wiring of the spherical semiconductor element so as to obtain an upper wiring pattern transfer material and a lower wiring pattern transfer material, provided that as to the transfer material which is, in the following step (2-c), placed on a side of the prepreg substrate on which side the portion of the spherical semiconductor element is exposed, a hole is also formed through the carrier sheet which hole such portion is able to pass through;
(2-c) locating and aligning each of the above mentioned wiring pattern transfer sheets, through a resin sheet in its uncured condition (provided that a hole is formed through the resin sheet which is to be placed on the side of the prepreg substrate on which side the portion of the spherical semiconductor element is exposed), on each side of the prepreg substrate in which the spherical semiconductor element is embedded while the exposed portion of the spherical semiconductor element is located through the holes of the carrier sheet and the resin sheet, followed by heating with pressing them so as to integrally bond them, whereby the prepreg substrate and the uncured resin sheets are made into an electrically insulating substrate while the wiring patterns are connected to each other with the wiring of the spherical semiconductor element; and
(2-d) removing the carrier sheets and leaving the wiring patterns and the bumps on the electrically insulating substrate so as to transfer them.

22. A process of producing a wiring board comprising at least the steps of:
(3-a) embedding at least a portion of a spherical semiconductor element in a prepreg substrate which is made of a curable resin composition in its uncured condition, and also embedding a passive element having terminal electrodes at its both ends respectively;
(3-b) forming respectively, on carrier sheets, bumps and conductive thin layers as well as wiring patterns which are to be connected to each other through a portion of the wiring of the spherical semiconductor element which portion is exposed so as to obtain an upper wiring pattern transfer material and a lower wiring pattern transfer material;
(3-c) locating and aligning each of the above mentioned wiring pattern transfer materials, through a resin sheet in its uncured condition (provided that a hole is formed through a region of the resin sheet which region is to face the conductive thin layer when the transfer material is so located and aligned), on each side of the prepreg substrate in which the spherical semiconductor element is embedded while the conductive thin layers are located on the terminal electrodes of the passive element, followed by heating with pressing them so as to integrally bond them, whereby the prepreg substrate and the uncured resin sheets are made into an electrically insulating substrate while the wiring patterns are connected to each other with the wiring of the spherical semiconductor element; and
(3-d) removing the carrier sheets and leaving the wiring patterns and the bumps on the electrically insulating substrate so as to transfer them.

23. A process of producing a wiring board in which a spherical semiconductor element is used, comprising at least the steps of:
(4-A) providing the spherical semiconductor element having a wiring on its surface;
(4-B) embedding a passive element in the form of a chip having a terminal electrode at its each end in each prepreg substrate which is made of a curable resin composition in its uncured condition, so that a part embedded upper prepreg substrate and a part embedded lower prepreg substrate are obtained;
(4-C) forming a space in a predetermined position in each of the part embedded upper prepreg substrate and the part embedded lower prepreg substrate;
(4-D) forming respectively, on carrier sheets, conductive thin layers and wiring patterns which are to be connected to each other by the wiring of the spherical semiconductor element, so that an upper transfer material and a lower transfer material are obtained;
(4-E) locating a resin sheet in its uncured condition in at least one of a space between the part embedded upper prepreg substrate and the part embedded lower prepreg substrate, a space between the part embedded upper prepreg substrate and the upper transfer material and a space between the part embedded lower prepreg substrate and the lower transfer sheet, and also locating the spherical semiconductor element between the part embedded upper prepreg substrate and the part embedded lower prepreg substrate, followed by aligning all of them;
(4-F) heating so as to bond the transfer sheets, the prepreg substrate, and the resin sheets while pressing them together so as to make the prepreg substrate and the resin sheets into an electrically insulating substrate while connecting the passive element to the wiring of the spherical semiconductor element; and
(4-G) removing the carrier sheets and leaving the wiring patterns and the bumps on the electrically insulating substrate so as to transfer them.

24. A process of producing a wiring board which contains a spherical semiconductor element, comprising at least the steps of:
(5-1) providing a transfer material by forming a predetermined first wiring pattern on a carrier sheet;
(5-2) mounting, on a predetermined position of the first wiring pattern of the transfer material, at least one spherical semiconductor element having a wiring on its surface so as to provide a first transfer material;
(5-3) providing a second transfer material by forming a predetermined second wiring pattern on a carrier sheet;
(5-4) superimposing a prepreg substrate made of a uncured resin composition and the two transfer materials such that the first wiring pattern and the second wiring patter are opposed through the prepreg substrate, followed by pressure bonding them at a heated temperature under an elevated pressure, so that the spherical semiconductor element is embedded into an electrically insulating substrate while the first wiring pattern and the second wiring pattern are connected by the wiring of the spherical semiconductor element; and
(5-5) removing the carrier sheets so as to transfer the first wiring pattern and the second wiring pattern.

25. A process of producing a wiring board which contains a spherical semiconductor element, comprising at least the steps of:
(6-1) providing a first carrier sheet comprising a first metal layer on its surface;
(6-2) mounting, on a second metal layer placed on a surface of a second carrier sheet, at least one spherical semiconductor element having a wiring on its surface;
(6-3) superimposing while aligning the first carrier sheet and the second carrier sheet such that their metal layers are opposed to each other through a prepreg substrate made of an uncured resin composition, followed by pressure bonding them at a heated temperature under an elevated pressure, so that a laminate is obtained in which the spherical semiconductor element is embedded into an electrically insulating substrate while the first metal layer and the second metal layer are connected to the spherical semiconductor element; and
(6-4) removing the first carrier sheet and the second carrier sheet from the laminate, followed by processing as predetermined to obtain a first wiring pattern a the second wiring pattern.
